(19) United States
(12) Patent Application Publication
(10) Pub. No.: US 2012/0072931 A1
(43) Pub. Date: Mar. 22, 2012

(54) SURFACE EMITTING SEMICONDUCTOR LASER, OPTICAL RECORDING HEAD, AND OPTICAL RECORDING APPARATUS

(76) Inventors: Masahiro Imada, Osaka (JP); Koujirous Sekine, Osaka (JP)

(21) Appl. No.: 13/375,407

(22) PCT Filed: Mar. 5, 2010
(86) PCT No.: PCT/JP2010/053635

§ 371 Date: Nov. 30, 2011

(30) Foreign Application Priority Data
Jun. 5, 2009 (JP) 2009-135923
Jun. 19, 2009 (JP) 2009-146259

(51) Int. Cl. G11B 7/1353; H01S 5/026; G11B 7/08

(52) U.S. Cl. 720/672; 369/112.02; 372/50.11; G9B/7.112; G9B/7.041

(57) ABSTRACT

Disclosed is an optical recording head which is provided with a surface emitting laser that emits laser light which is efficiently introduced into a waveguide through a grating coupler (diffraction grating). Specifically disclosed is an optical recording head which is provided with a surface emitting laser comprising at least a light source, and a waveguide that is connected thereto through a diffraction grating and irradiates a recording medium with the light from the light source. The light source has a two-dimensional photonic crystal structure in the surface that faces the waveguide. Regions of the two-dimensional photonic crystal structure other than the region facing the diffraction grating are converted, and the region facing the diffraction grating serves as a surface emitting.

### TECHNICAL FIELD

The present invention relates to a surface emitting semiconductor laser, an optical recording head, and an optical recording apparatus.

### BACKGROUND

Over recent years, with an increase in density of information recording media, recording methods of various types are being proposed and of these, there is a heat assisted magnetic recording method. Such a heat assisted magnetic recording method is a method, in which a recording medium is locally heated during recording for magnetic softening and in the state where coercivity has been decreased, recording is carried out; and thereafter heating is terminated, followed by natural cooling to ensure the stability of recorded magnetic bits.

In the heat assisted magnetic recording method, it is desirable to instantaneously heat a recording medium and also a heating mechanism and the recording medium are not allowed to be in contact with each other. Therefor, heating is commonly carried out by use of light absorption and a method employing light for heating is referred to as an optically assisted type. When high-density recording is carried out using such an optically assisted type, a minute light spot having a size of at most the wavelength of used light is required.

An optical recording head employing near-field light (referred to also as near visual field light) as a minute light spot is disclosed in Patent Document 1 as described below.

The optical recording head disclosed in Patent Document 1 is provided with a waveguide having a writing magnetic pole, as well as a core layer and a clad layer adjacent to the writing magnetic pole. The core layer is provided with a diffraction grating (referred to as a grating coupler) to introduce light into the core layer. Laser light is irradiated to this grating coupler to introduce laser light into the core layer. Light having been introduced into the core layer is collected at a focus located in the vicinity of the tip portion of the core layer and then a recording medium is heated by light emitted from the tip portion for writing using the writing magnetic pole. An element having a waveguide with such a light collecting function is referred to as a waveguide-type solid immersion mirror (PSIM: Planer Solid Immersion Mirror), and the PSIM of Patent Document 1 is provided with a grating coupler as described above.

When light is introduced into the waveguide using this grating coupler, the usage efficiency of light needs to be taken into consideration.

A recording head portion provided with the above PSIM is occasionally referred to as an HAMR (Heat Assisted Magnetic Recording) head. Patent Document 2 discloses a slider in which this HAMR head is provided and further a surface emitting laser (VCSEL: Vertical Cavity Surface Emitting Laser) for irradiation of laser light so as for light to be input into the HAMR head is electrically connected via a conductive bridge and mechanically fixed. It is described that when the slider is provided with such an HAMR head and also a surface emitting laser, the mass of a movable portion and mechanical and aerodynamic bottlenecks are reduced, resulting in excellent control characteristics.

### PRIOR ART DOCUMENTS

### Patent Documents

Patent Document 1: U.S. Pat. No. 6,944,112 specification

Patent Document 2: U.S. Patent Application Publication No. 2008/0002298 specification

### BRIEF DESCRIPTION OF THE INVENTION

### Problems to be Solved by the Invention

However, in both Patent Documents 1 and 2, no method to efficiently introduce laser light into a waveguide from a grating coupler is taken into consideration.

In view of the above problems, the present invention was completed, and an object thereof is to provide a surface emitting laser to generate laser light introduced efficiently into a waveguide from a grating coupler (a diffraction grating), an optical recording head provided therewith, and an optical recording apparatus.

### Means to Solve the Problems

The above problems are solved by the following constitution:

1. An optical recording head comprising: a light source; and a waveguide for irradiating a recording medium with light from the light source, the light being joined to the waveguide via a diffraction grating; wherein the light source is a surface emitting laser in which a two-dimensional photonic crystal structure is provided in a surface on a side opposite to the waveguide, a region except a region opposite to the diffraction grating is covered in the two-dimensional photonic crystal structure, and the region opposite to the diffraction grating is a surface emitting region.

2. The optical recording head, described in item 1, wherein the surface emitting laser is a surface emitting semiconductor laser in which a member to cover the two-dimensional photonic crystal structure is a first electrode to form a resonator region together with a second electrode opposite to the first electrode.

3. The optical recording head, described in item 1, wherein the surface emitting laser, in which a member to cover the two-dimensional photonic crystal structure is a light shielding member, emits light by excitation light irradiated to a side opposite to a side where the light shielding member of the surface emitting laser is located.

4. The optical recording head, described in any one of items 1-3, wherein the light source is fixed to the waveguide.

5. The optical recording head, described in item 3, wherein a photoexcitation source to emit excitation light to allow the surface emitting laser to emit light is provided and the surface emitting region is not irradiated with the excitation light.

6. The optical recording head, described in any one of items 1-5, wherein the recording medium is a magnetic recording medium and a slider moving relatively to the magnetic recording medium having at least the light source, the waveguide, and a magnetic recording section is provided.

7. In a surface emitting semiconductor laser, arranged opposite to a waveguide having a gating coupler, to eject light to be introduced into the waveguide toward a grating coupler, the surface emitting semiconductor laser comprising: a semiconductor laminated portion having a first clad layer, a second clad layer, and an active layer, sandwiched between the first clad layer and the second clad layer, to generate light of a predetermined wavelength by carrier injection; a first electrode connected to the first clad layer; and a second electrode connected to the second clad layer; wherein the first clad layer is provided with a diffraction grating having a constitution in which refractive index is changed with a period corresponding to the predetermined wavelength in an in-plane direction, light having been generated in the active layer by optical coupling with the active layer is introduced, light of the predetermined wavelength having been introduced is diffracted for laser oscillation, and a traveling direction of at least part of light is converted into a vertical direction with respect to the in-plane direction; wherein, in the diffraction grating, a region except a region opposite to the grating coupler is covered and a region, opposite to the grating coupler, to eject light having been converted into the vertical direction is a surface emitting region; and wherein a member to cover the diffraction grating is the first electrode and a resonator region to carry out laser oscillation, together with the second electrode opposite to the first electrode is formed.

8. The surface emitting semiconductor laser, described in item 7, wherein the surface emitting region is provided in end portion of the diffraction grating; and an optical intensity distribution of light ejected from the surface emitting region is maximized in the vicinity of a border between the resonator region and the surface emitting region in a first direction toward the surface emitting region from the resonator region and decreased with separation toward the surface emitting region from the border.

9. The surface emitting semiconductor laser, described in item 8, wherein a region provided with the diffraction grating when viewed from the side where light is ejected from the surface emitting region has a reed shape whose long side is the first direction.

10. The surface emitting semiconductor laser, described in item 8 or 9, wherein in the diffraction grating, concave portions arranged in the first clad layer with the period are filled with a material having refractive index differing from that of a material for the first clad layer.

11. The surface emitting semiconductor laser, described in item 10, wherein the concave portions are cavity-shaped concave portions and the cavity-shaped concave portions of the resonator region and the surface emitting region are arranged in a square grid manner in the first direction and in a direction vertical to the first direction.

12. The surface emitting semiconductor laser, described in item 10, wherein the concave portions of the resonator region are cavity-shaped ones arranged in a square grid manner in the first direction and a direction vertical to the first direction; and the concave portions of the surface emitting region are striped groove-shaped ones arranged in the direction vertical to the first direction and a period of the first direction is arrange so as to be the same as the period of the square grid.

13. The surface emitting semiconductor laser, described in item 10, wherein the concave portions are cavity-shaped ones and the cavity-shaped concave portions of the resonator region are arranged in a square grid manner in the first direction and a direction vertical to the first direction; and in the cavity-shaped concave portions of the surface emitting region, the period of the direction vertical to the first direction is the same as that of the square grid of the resonator region and a period of the first direction is arranged so as to be differing from the period of the square grid.

14. The surface emitting semiconductor laser, described in item 10, wherein the concave portions of the resonator region are cavity-shaped ones arranged in a square grid manner in the first direction and in a direction vertical to the first direction; and the concave portions of the surface emitting region are striped groove-shaped ones arranged in the direction vertical to the first direction and a period of the first direction is arranged so as to be differing from the period of the square grid.

15. The surface emitting semiconductor laser, described in item 13 or 14, wherein in the first direction and in a cross-section of the concave portions in a vertical direction of a main flat surface on an opposite side to a surface facing to the active layer of the first clad layer, with regard to the concave portions of the surface emitting region, a width of the concave portions of the first direction is decreased or increased as a depth from the main flat surface is increased and the concave portions are asymmetrical with respect to the axis vertical to the main flat surface.

16. The surface emitting semiconductor laser, described in item 11 or 13, wherein a cross-section of a depth direction of the concave portions from a main flat surface on an opposite side to a surface facing the active layer of the first clad layer are the same, and a cross-section of the concave portions in the resonator region differs from the cross-section of the concave portions in the surface emitting region.

17. The surface emitting semiconductor laser, described in any one of items 10-16, wherein a depth of the concave portions from a main flat surface of an opposite side to a surface facing the active layer of the first clad layer differs in the resonator region and the surface emitting region.

18. The surface emitting semiconductor laser, described in item 17, wherein the depth of the concave portions in the surface emitting region is smaller in the end portion of the surface emitting region in the direction distant from the border than in a vicinity of the border.

19. The surface emitting semiconductor laser, described in any one of items 8-18, wherein a width of a region where the diffraction grating in a direction vertical to the first direction is located is a width of the grating coupler irradiated with light or more.

20. In an optical recording head to carry out information recording on a recording medium using light, the optical recording head comprising: a surface emitting semiconductor laser described in any one of items 7-19; a slider moving relatively to the recording medium; and the waveguide, in which light irradiated by the surface emitting semiconductor laser is introduced into a side of the slider substantially vertical to the recording surface of the recording medium and the thus-introduced light is propagated toward the recording medium.

21. The optical recording head described in item 20, wherein the surface emitting semiconductor laser is fixed to the waveguide.

22. An optical recording apparatus comprising the optical recording head described in item 20 or 21 and the recording medium.

### Effects of the Invention

According to the surface emitting semiconductor laser of the present invention, laser light emitted from the surface emitting semiconductor laser to irradiate a grating coupler (a diffraction grating) exhibits intensity distribution so as to be efficiently introduced into a waveguide.

Accordingly, the surface emitting semiconductor laser of the present invention can generate laser light to be efficiently introduced into a waveguide provided with a grating coupler.

Further, the optical recording head of the present invention is provided with a waveguide having a grating coupler (a diffraction grating) and a surface emitting laser to irradiate the grating coupler with optical intensity distribution so as for light to be efficiently introduced into the waveguide.

Accordingly, the optical recording head of the present invention can efficiently irradiate a recording medium with light from a light source.

### BRIEF DESCRIPTION OF THE DRAWINGS

FIG. 1 is a view showing an example of the schematic constitution of an optical recording apparatus mounted with an optically assisted magnetic recording head (an optical recording head);

FIG. 2 is a view schematically showing an optical recording head and its periphery using a cross-section;

FIG. 3 is a view showing a front elevational view of a waveguide;

FIG. 4 is a view showing the cross-section in axis C of the waveguide shown in FIG. 3 and the cross-section of a light source;

FIG. 5 is a view schematically showing one example of the schematic constitution of a light source in which FIG. 5a is a top view and FIG. 5b is a cross-sectional view;

FIGS. 6a and 6b each are a cross-sectional view schematically showing one example of the schematic constitution of a light source;

FIG. 7 is a top view schematically showing one example of the schematic constitution of a light source;

FIG. 8 is a view schematically showing one example of a light source in which FIG. 8a is a top view and FIG. 8b is a cross-sectional view;

FIGS. 9a and 9b each are a view showing a combination example of a light source and a waveguide;

FIG. 10 is a view schematically showing one example of the schematic constitution of a light source in which FIG. 10a is a top view and FIG. 10b is a cross-sectional view;

FIG. 11 is a view showing a combination example of a light source and a waveguide;

FIG. 12 is a view showing an example of a plasmon antenna;

FIG. 13 is a view schematically showing another example of an optical recording head and its periphery using a cross-section;

FIG. 14 is a view showing the cross-section of a waveguide and the cross-section of a light source in another example of an optical recording head;

FIG. 15 is a view schematically showing the schematic constitution of one example of a light source in which FIG. 15a is a top view and FIG. 15b is a cross-sectional view;

FIG. 16 is a view schematically showing the schematic constitution of one example of a light source in which FIG. 16a is a top view and FIG. 16b is a cross-sectional view;

FIGS. 17a and 17b each are a cross-sectional view schematically showing the schematic constitution of one example of a light source;

FIG. 18 is a top view schematically showing the schematic constitution of one example of a light source;

FIG. 19 is a view schematically showing the schematic constitution of one example of a light source in which FIG. 19a is a top view and FIG. 19b is a cross-sectional view;

FIGS. 20a and 20b each are a view showing a combination example of a light source and a waveguide;

FIG. 21 is a view schematically showing the schematic constitution of one example of a light source in which FIG. 21a is a top view and FIG. 21b is a cross-sectional view; and

FIG. 22 is a view showing a combination example of a light source and a waveguide.

### PREFERRED EMBODIMENTS OF THE INVENTION

The present invention relates to a surface emitting semiconductor laser to emit laser light (referred to also as light) able to be efficiently introduced into a waveguide having a grating coupler and an optical recording head provided with the surface emitting semiconductor laser. This optical recording head can be used for an optical recording apparatus to carry out recording on a magnetooptical recording medium or an optical recording medium.

A surface emitting semiconductor laser of the embodiments of the present invention, a heat assisted magnetic recording head provided with the laser, and an optical recording apparatus will now be described but the present invention is not limited to the embodiments. Incidentally, in each of the embodiments, mutually the same portions and equivalent portions are assigned with the same symbols to appropriately omit overlapping description.

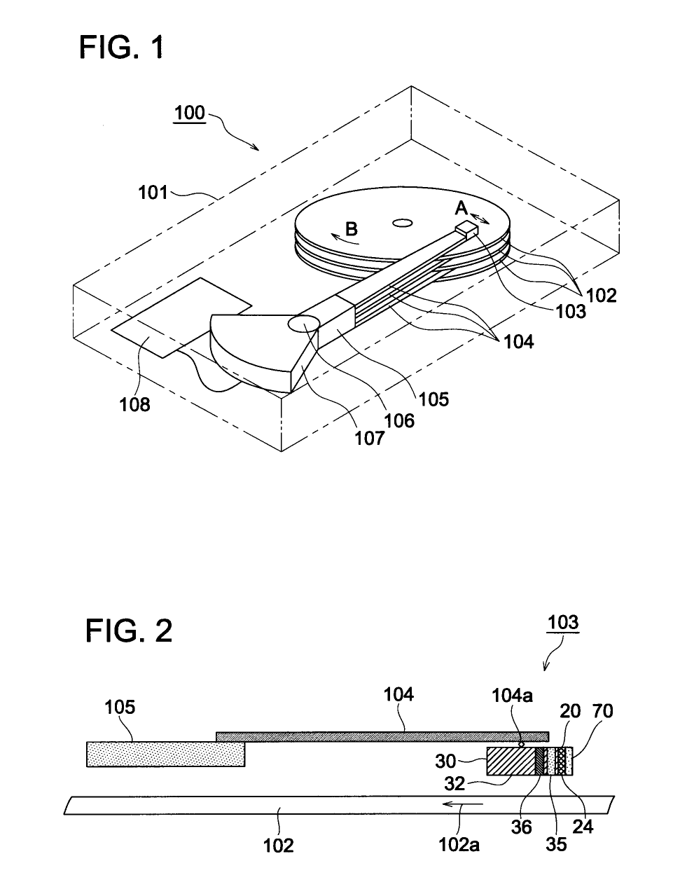

FIG. 1 shows a schematic constitution example of an optical recording apparatus (for example, a hard disk apparatus) mounted with an optically assisted magnetic recording head provided with a surface emitting semiconductor laser in the embodiments of the present invention. This optical recording apparatus 100 is provided with following (1)-(6) in a housing 101.

(1) Recording disk (recording medium) 102

(2) Suspension 104 supported by an arm 105 provided in the arrow A direction (tracking direction) rotatably around a supporting shaft 106 as a support point being

(3) Tracking actuator 107, attached to the arm 105, to rotationally drive the arm 105

(4) Optically assisted magnetic recording head (hereinafter, referred to as an optical recording head 103) containing the suspension 104 and a slider 30 attached to the tip portion thereof via a joint member 104a

(5) Motor (not shown) to rotate the disk 102 in the arrow B direction

(6) Control section 108 to carry out control for optical recording on the disk 102 using the tracking actuator 107, the motor, and the optical recording head 103 to generate light irradiated based on writing information for recording on the disk 102 and a magnetic field

In the optical recording apparatus 100, a constitution is made in which the slider 30 can relatively move above the disk 102 while floating.

FIG. 2 schematically shows an optical recording head 103 and its periphery using a cross-section as one example of the optical recording head 103 according to the present invention. The optical recording head 103 is an optical recording head employing light for information recording on a disk 102 and incorporates a slider 30, a waveguide 20, a surface emitting semiconductor laser (hereinafter, referred to as a light source 70) serving as a light source, a magnetic recording section 35, and a magnetic information regeneration section 36.

The waveguide 20 is referred to also as a waveguide-type solid immersion mirror (PSIM: Planer Solid Immersion Mirror) and provided with a diffraction grating (referred to also as a grating coupler) to introduce light into the waveguide. The light source 70 is a surface emitting semiconductor laser provided with a two-dimensional photonic crystal structure (a structure in which the refractive index in the in-plane direction of a structural body periodically changes) which is one of the diffraction gratings to irradiate the grating coupler with light introduced into the waveguide 20.

Incidentally, in the waveguide 20 and the light source 70 of FIG. 2, when a specific example is described below, other symbols are added to symbols 20 and 70 to be shown as waveguides 20A-20C and light sources 70A-70G combined with these waveguides.

The slider 30 moves relatively, while floating, to the disk 102, a magnetic recording medium. For the material of the slider 30, a hard material exhibiting large abrasion resistance is preferably used For example, a ceramic material containing Al₂O₃, AlTiC, zirconia, or TiN may be used. Further, for abrasion prevention treatment, to enhance abrasion resistance, the surface of the disk 102 side of the slider 30 may be subjected to surface treatment such as DLC (Diamond Like Carbon) coating.

Further, the surface opposite to the disk 102 of the slider 30 has an air bearing surface 32 (referred to also as an ABS (Air Bearing Surface)) to enhance floating characteristics.

It is necessary to stabilize the floating of the slider 30 in the state of being close to the disk 102 and to appropriately apply pressure to suppress the floating power of the slider 30. Therefor, the suspension 104 fixed on the slider 30 functions to track the slider 30 and also to appropriately apply pressure to suppress the floating power of the slider 30.

In the slider 30, on the side of the inflow side of the disk 102, the waveguide 20 and the light source 7 are provided almost vertically to the recording surface of the disk 102. The light source 70 is fixed near the waveguide 20 so that light having been emitted from the light source 70 irradiates a grating coupler (hereinafter, referred to as a coupler) being a diffraction gratin provided for the waveguide 20. It is preferable that the waveguide 20 and the light source 70 be integrally fixed to the slider 30, since light emitted from the light source 70 is stably introduced into the waveguide 20 independently of the movement of the slider 30, resulting in stable magnetooptical recording.

Light having been emitted from the light source 70 is introduced into the waveguide 20 and then the light having been introduced into the waveguide 20 is moved to the lower end surface 24 of the waveguide 20 to be ejected toward the disk 102 as irradiation light to heat the disk 102. Herein, in FIG. 2, a plasmon antenna 24d to be described later provided in the location where light of the lower end surface 24 is ejected or in its vicinity is omitted.

A minute light spot being near-field light generated by the plasmon antenna 24d provided in the lower end surface 24 is irradiated to the disk 102 and thereby the temperature of an irradiated portion of the disk 102 is temporarily increased to decrease the coercivity of the disk 102. In the portion having the thus-decreased coercivity via light irradiation, magnetic information is written using the magnetic recording head 35.

The magnetic recording head 35 is preferably provided adjacent to the waveguide 20 as close as possible to carry out efficient magnetic recording on the recording surface of the disk 102 having been heated by light and further, preferably arranged on the downstream side of the waveguide 20 when viewed from the moving direction (the arrow 102a direction) of the recording surface via rotation of the disk 102. Further, on the disk leaving side of the magnetic recording head 35 or the disk entering side of the waveguide 20, a magnetic information regeneration section 36 to read out magnetic recording information having been written in the disk 102 may be provided.

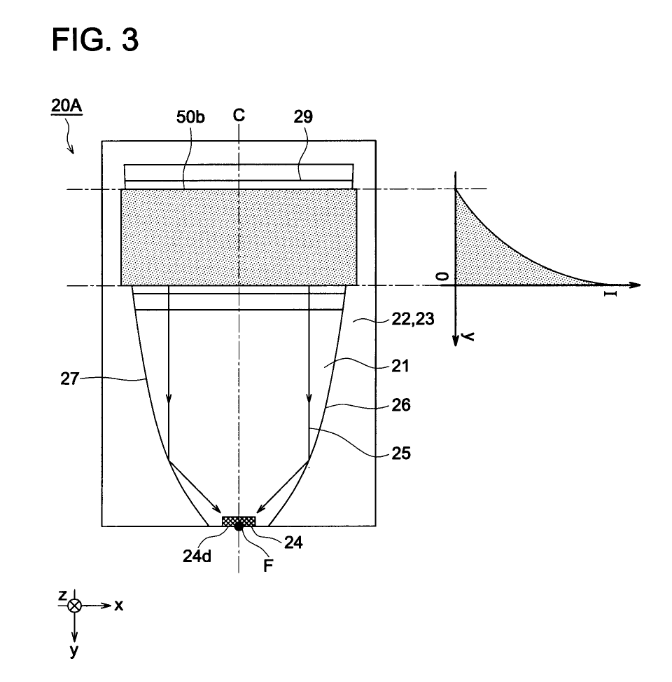

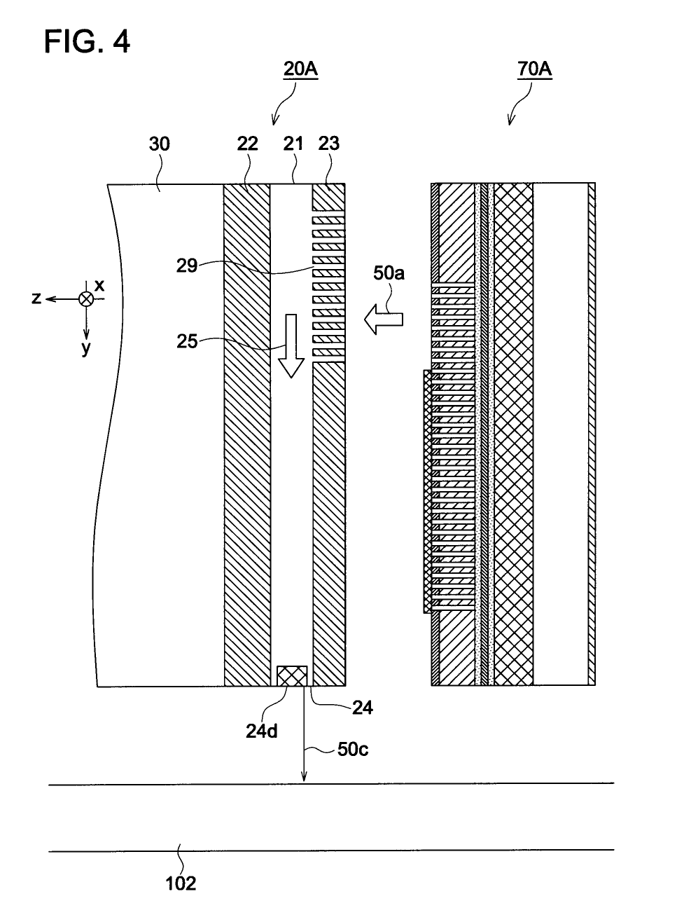

The waveguide 20 will now be described. A front elevational view (transparent view) of a waveguide 20A and a cross-sectional view in axis C of FIG. 3 are shown in FIG. 3 and FIG. 4, respectively. In FIG. 4, a light source 70A to emit light to be introduced into the waveguide 20A is shown together. The waveguide 20A has a core layer 21 constituting the waveguide as well as a lower clad layer 22 and an upper clad layer 23 to form a grating coupler (hereinafter, referred to as a coupler 29) to introduce light 50a ejected from the light source 70A into the core layer 21.

The waveguide 20A can be structured with a plurality of layers using materials of different refractive index. The refractive index of the core layer 21 is larger than the refractive indexes of the lower clad layer 22 and the upper clad layer 23. This refractive index difference constitutes the waveguide 20A. Light within the core layer 21 is confined in the core layer 21 interior and then efficiently moved in the arrow 25 direction to reach the lower end surface 24.

The refractive index of the core layer 21 is preferably about 1.45-4.0 and the refractive indexes of the lower clad layer 22 and the upper clad layer 23 are preferably about 1.0-2.0. However, these ranges are not limited.

The core layer 21 is formed of Ta₂O₅, TiO₂, or ZnSe. The thickness thereof is preferably about 20 nm-500 nm. However, this range is not limited. Further, the lower clad layer 22 and the upper clad layer 23 are formed of SiO₂, air, or Al₂O₃. The thicknesses thereof are preferably about 200 nm-2000 nm. However, this range is not limited.

The core layer 21 is provided with sides 26 and 27 formed so as to constitute a practically parabolic outline to reflect light having been coupled by the coupler 29 toward the focus F to be collected at the focus F. In FIG. 3, the center axis in which the outline is bilaterally symmetrical in the parabola is shown by axis C (a line passing through the focus F vertically to the directrix (not shown)) and the focus of the parabola is shown as the focus F. In the sides 26 and 27, a reflective material such as, e.g., gold, silver, or aluminum may be provided for the aid to further reduce light reflection loss. The thicknesses of the sides 26 and 27 are extremely smaller than other dimensions in the core layer 21 and thereby the outline of the core layer 21 is practically specified.

Further, the lower end surface 24 of the core layer 21 of the waveguide 20A has a flat surface shape seen as if the tip of the parabola is cut in the direction almost vertical to axis C. Light 50a emitted from the focus F is rapidly diverged. Therefore, the shape of the lower end surface 24 is preferably allowed to be flat, since the focus F can be arranged closer to the disk 102 and collected light enters the disk 102 prior to wide divergence. The focus F may be formed on the lower end surface 24 or outside the lower end surface 24. Incidentally, in the present example, the lower end surface 24 is allowed to be flat but needs not always to be flat.

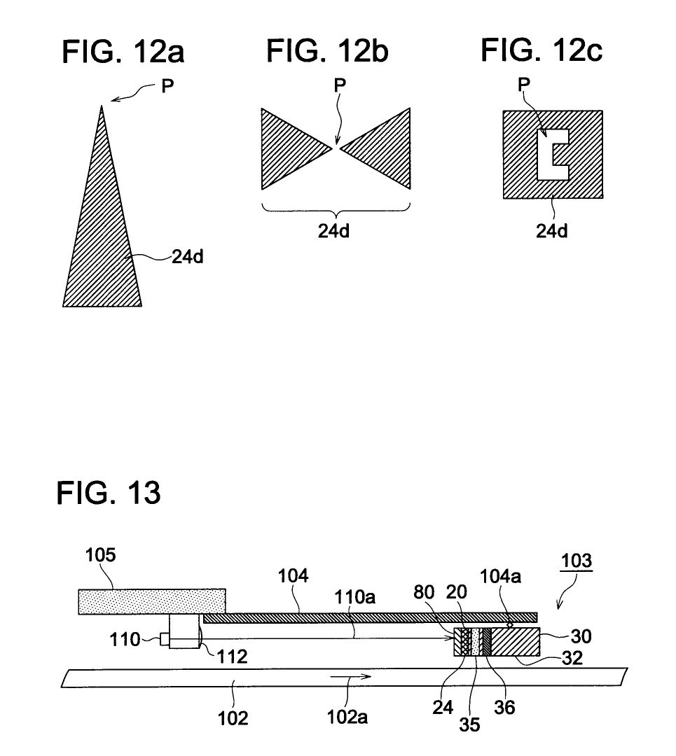

In the focus F of the core layer 21 or in the vicinity thereof a plasmon antenna 24d for near-field light generation may be arranged. Specific examples of the plasmon antenna 24d are shown in FIG. 12.

In FIG. 12, FIG. 12a shows a plasmon antenna 24d formed of a triangular flat metal thin film and FIG. 12b shows a plasmon antenna 24d formed of a bow-tie-type flat metal thin film in which each of them is formed with an antenna having a peak P featuring a curvature radius of at most 20 nm. Further, FIG. 12c shows a plasmon antenna 24d formed of a flat metal thin film having an opening having an antenna of a peak P featuring a curvature radius of at most 20 nm. The material for the metal thin film of any of the plasmon antennas 24d includes aluminum, gold, and silver.

When light acts on any of the plasmon antennas 24d, in the vicinity of the peak P, near-field light is generated, and thereby recording can be carried out using light of extremely small spot size. Namely, at the focus F of the core layer 21 or in the vicinity thereof a plasmon antenna 24d is provided to generate a localized plasmon, and thereby the size of a light spot having been formed at the focus can be further reduced, which is advantageous in high-density recording. Incidentally, the peak P of the plasmon antenna 24d is preferably located at the focus F.

With regard to light irradiated to the coupler 29 and then introduced into the waveguide 20A, on the basis of the effective refractive index of the waveguide mode of the core layer 21 and the period of the coupler 29, an appropriate incident angle to the coupler 29 with highest introduction efficiency is determined. The appropriate incident angle also depends on the wavelength of incident light. This incident angle may be nearly vertical to the waveguide 20A if appropriate, or may have an appropriate angle. FIG. 4 shows an example in which the incident angle is 0°.

FIG. 3 schematically shows the irradiation region 50b of light 50a for irradiation to the coupler 29 using the light source 70A and the optical intensity distribution on axis C. Light 50a has intensity distribution with a slope shape in which the optical intensity of the front side in the traveling direction (the +y direction or the arrow 25 direction) of light having been introduced into the waveguide 20A is largest and then the optical intensity exponentially decreases as light having been introduced into the core layer of the waveguide 20A travels toward the opposite direction (the −y direction) to the traveling direction thereof. And, the shape is a columnar one having thickness in the width direction (the x direction) of the coupler 29. Light 50a having optical intensity distribution in which such a slope is an exponential shape is efficiently introduced into the core layer 21 from the coupler 29, compared with light having Gaussian shape in which the irradiation region for irradiation to the coupler 29 has a common circular shape and then in the optical intensity distribution of the diameter direction passing through the center of the circular shape, the intensity of the center of the circle is largest.

It is presumed that when in the optical intensity of light irradiated to the coupler, the slope has an exponential shape, efficient introduction is carried out into the core layer 21 from the coupler 29 on the basis of the case where due to the reverse traveling property of light, light traveling in the reverse direction to the arrow 25 direction in the core layer 21 is ejected from the coupler 29. In other words, with respect to light reversely traveling in the core layer 21, light of the largest intensity is diffracted to the outside from the vicinity of the border with the coupler 29 in which the loss due to the coupler 29 is small and then as light approaches the coupler 29 side, the loss due to the coupler 29 is increased, resulting in a decrease in the optical intensity diffracted to the outside.

There exists a light source having optical intensity distribution whose slope is an exponential shape (a diffraction grating coupled surface emitting laser employing a single-dimensional grating) (M. Imada, et al., IEEE Journal of Quantum Electronics, Vol. 35, No. 9, p. 1277 (1999)). However, the width of the oscillation region whose slope corresponds to the thickness of an exponential shape is about several μm, which is smaller than a width of, for example, about 50 μm of the coupler 29. In a laser light source in which the width of the oscillation region is several μm, when the width of the oscillation region is attempted to increase so as to match the width of the coupler 29, the wavelength and the optical intensity distribution in the width direction become multimodal and thereby no optimum shape or wavelength for the coupler 29 can be realized.

As a method to expand the width of the emitting region, there is cited a semiconductor laser, enabling to carry out surface emission, provided with a two-dimensional diffraction grating (a two-dimensional photonic band structure) disclosed in, for example, Japanese Patent No. 3983933. With regard to beams ejected from this semiconductor laser, it is described that extremely narrow ejection angle (1.8°) is achieved in a far-field image but the beam shape (optical intensity distribution) is not disclosed.

The inventors conducted diligent investigations on a surface emitting semiconductor laser to generate light having optical intensity distribution in which a slope having thickness to efficiently introduce light into the core layer 21 from the coupler 29 has an exponential shape, and then the present invention was completed. The surface emitting semiconductor laser (a light source) according to the present invention will now be described.

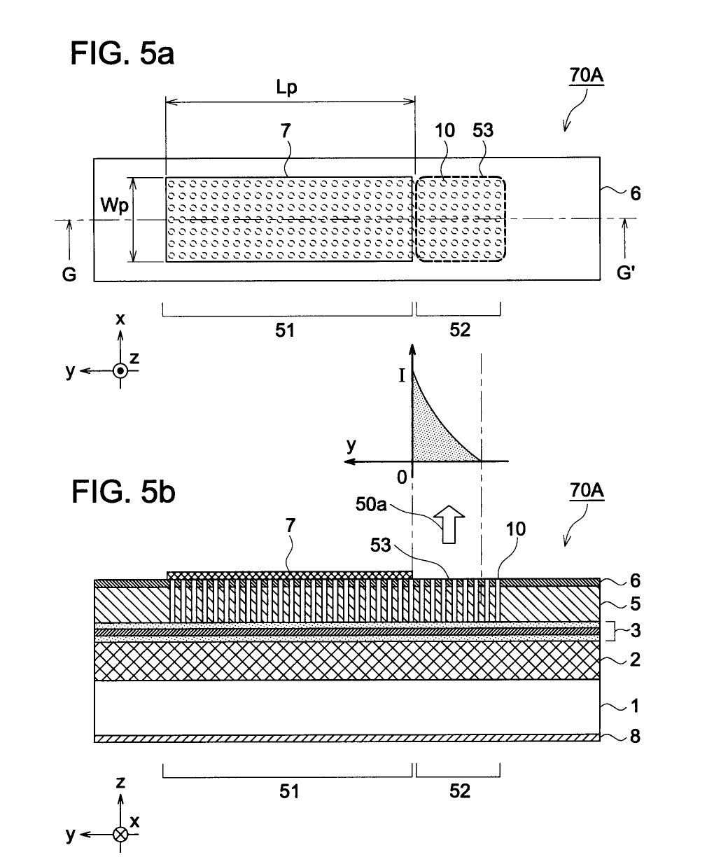

FIG. 5 schematically shows one example of the schematic constitution of a two-dimensional photonic crystal surface emitting semiconductor laser which is the light source 70A according to the present invention.

FIG. 5a is a top view of the light source 70A and FIG. 5b is a cross-sectional view taken along the line G-G′ of FIG. 5a. The light source 70A is provided with a substrate 1, a second clad layer 2 formed on one main surface of the substrate 1, an active layer 3 formed on the second clad layer 2, a semiconductor laminated portion having a first clad layer 5 formed on the active layer 3 and a contact layer 6, a first electrode 7 formed on the contact layer 6, and a second electrode 8 formed on the other main surface opposite to the one main surface in the substrate 1.

The first electrode 7 is provided so as to cover part of concave portions 10 forming a two-dimensional photonic crystal structure to be described later. The second electrode 8 is provided over the entire surface of the other main surface. Via such a constitution, the two-dimensional photonic crystal structure has a portion located between the first electrode 7 and the second electrode 8 and a portion in the state of being open with no first electrode 7 to selectively eject laser light from the surface on the side where the first electrode 7 is formed. Herein, no light ejected by the light source 70A is transmitted through either the first electrode 7 or the second electrode.

The substrate 1 is, for example, an n-type GaAs substrate. The second dad layer 2 is, for example, an n-type semiconductor layer in which an electron is a carrier, being formed of, for example, of n-type Al_{0.4}Ga_{0.6}As. The first clad layer 5 is, for example, a p-type semiconductor layer in which a hole (positive hole) is a carrier, being formed of, for example, p-type AlₓGaₐ₍₁₋ₓ₎As. The contact layer 6 is, for example, a p-type semiconductor layer in which a hole (positive hole) is a carrier, being formed of, for example, p+-type GaAs.

The conductivity type of each semiconductor layer in the first clad layer 5 and the second clad layer 2 is not limited to the above one. For example, as in a buried tunnel junction (BTJ) type, the upper layer (the first clad layer 5 side) of the active layer 3 may have a structure having p-type and n-type semiconductor layers differing in conductivity type.

As described above, the active layer 3 is sandwiched by a second clad layer 2 and a semiconductor layer incorporating a contact layer 6 and a first clad layer 5 to generate (emit) light via carrier injection. For the active layer 3, any appropriate well-known common material and structure are employable, and the material and the structure are selected so as to emit a predetermined wavelength based on the intended usage. The active layer 3 is allowed to have a distorted quantum well structure constituted of, for example, a 3-period InGaAs well layer, GaAs barrier layer, and separate confinement layer (SCH layer).

The first clad layer 5 and the second clad layer 2 are formed of a material having refractive index smaller than that of the active layer 3 and also provided with the function to confine light in the active layer 3. Further, the refractive index of the first clad layer 5 is preferably larger than that of the second clad layer 2. Even when a two-dimensional photonic crystal structure is formed by increasing the refractive index of the first clad layer 5, the average refractive index of the first clad layer 5 is not excessively decreased. Thereby, the decrease of the ratio of light distributing in a layer where a photonic crystal structure is formed is prevented and thereby the decrease of the ratio of optical coupling with a diffraction grating (a photonic crystal structure) (referred to as optical coupling coefficient) can be prevented.

The active layer 3 is sandwiched by the first clad layer 5 and the second clad layer 2 to form a double hetero-junction and then carriers are confined, and thereby carriers contributing to light emission are concentrated in the active layer 3. The contact layer 6 is placed between the first electrode 7 and the first clad layer 5 to electrically connect them. Between the first clad layer 5 and the active layer 3, another layer such as a carrier stop layer functioning as a potential barrier against electrons moving toward the first clad layer 5 from the active layer 3 via carrier overflow may be mediated.

In the first clad layer 5 and the contact layer 6, as shown in FIG. 5a and FIG. 5b, there is a two-dimensional photonic crystal structure in which a plurality of cavity-shaped concave portions 10 are formed so as to be periodically arranged in the x direction and in they direction vertical to the x direction.

The two-dimensional photonic crystal structure is two-dimensionally provided with a refractive index period and formed in such a manner that a material having refractive index differing frown those of materials to form the first clad layer 5 and the contact layer 6 is arranged, as grid points, in 2 directions of x and y at right angles to each other with a predetermined period (grid distance or grid constant). In the present embodiments, the grid points are square grids constituted of columnar concave portions 10 formed in the first clad layer 5 and the contact layer 6. The shape of the concave portion 10 is a columnar one with no limitation to this shape, being possibly a quadrangular prism, a triangular prism, or a circular cone.

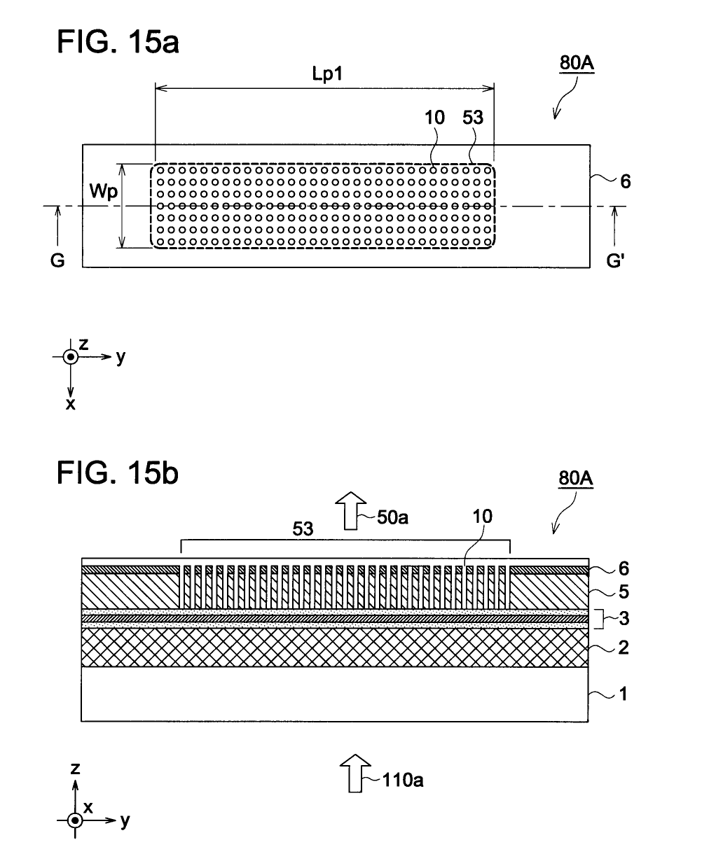

The interior side of the depression of the concave portion 10 is filled with a material having refractive index differing from that of a material to form the first clad layer 5. For example, the material of the first clad layer 5 is allowed to be Al_{0.4}Ga_{0.6}As (refractive index: 3.306), and then SiO₂ (refractive index: 1.5) or SiN (refractive index: 2.0) is cited as a material to fill the concave portion 10. Incidentally, as shown in FIG. 15b, for example, SiO₂ which is a material filing the concave portion 10 is provided, as a protective film, entirely on the contact layer 6.

When formed by etching from the contact layer 6 side, concave portions 10 are formed at least on the surface side of the contact layer 6 making contact with the first electrode 7, depending though on the production method. This two-dimensional photonic crystal structure selects the wavelength of light laser-oscillated in the active layer 3. As shown in FIG. 5a, when viewed from the contact layer 6 side, the region where concave portions 10 are formed has a reed shape. Of lights having leaked from the active layer 6 and then having been introduced into the two-dimensional photonic crystal structure, light having wavelength coinciding with the periodic distance of the concave portions 10 in this reed shape is resonated.

As the bottom surface of the concave portions 10 is close to the active layer 3, optical coupling efficiency with respect to the two-dimensional photonic crystal structure can increase. The concave portions 10 may reach the contact layer 6 and the first clad layer 5, but reaching the active layer 3 is not preferable. When the concave portions 10 reach the active layer 3, namely, the photonic crystal and the active layer 3 become close to each other, during etching for concave portion 10 formation, the active layer 3 may be damaged.

The two-dimensional photonic crystal structure emitting semiconductor laser as the light source 70A described above is one of the grating coupled surface emitting lasers and is provided with a two-dimensional photonic crystal structure of a preferred embodiment as a grating (a diffraction grating). With regard to the surface emitting laser, laser light is emitted vertically to the main surface of the element. In the light source 70A according to the present invention, the active layer 3 is parallel to the main surface and a diffraction grating is provided. This diffraction grating converts the traveling direction of light into about 180° and about 90° at the same time. In the light source 70A, a laser resonator is formed by the about 180° conversion, and light is emitted in the vertical direction by the about 90° conversion.

As the diffraction grating to convert the traveling direction of light in this manner, other than the above two-dimensional photonic crystal structure, for example, a two-dimensional photonic quasicrystal structure is cited. The two-dimensional photonic quasicrystal structure is a crystal structure having rotational symmetry with no translational symmetry, for example, parallel to the x direction and they direction as described above.

The first electrode 7 is constituted of a material through which light resonated in the two-dimensional photonic crystal structure is not transmitted and formed so as to cover other portions except the end portion of the side of the short side of the reed shape in the region where concave portions 10 are formed, as shown in FIG. 5a.

The region of the concave portions 10 covered by the first electrode 7 is a laser oscillation region located between the first electrode 7 and the second electrode 8, being referred to as a resonator region 51. In the resonator region 51, a voltage is applied between the first electrode 7 and the second electrode 8, whereby carriers are injected into the active layer 3 and then at a voltage of at least a predetermined value, light is emitted from the active layer 3. Light generated in the active layer 3 leaks to the two-dimensional photonic crystal structure to be introduced thereinto for laser oscillation. In the resonator region 51, width Wp is preferably at least the width of the coupler 29 to enable to thoroughly irradiate the width direction (the x direction) of the coupler 29, and length Lp is preferably at least the length in which laser oscillation and oscillation wavelength are stabilized.

Light having been oscillated in the resonator region 51 can travel in the two-dimensional photonic crystal structure in the −y direction (the first direction), and light having reached the region which is not covered by the first electrode 7 (the two-dimensional photonic crystal structure is open) is ejected, as coherent laser light, to the outside from the emitting surface 53. In FIG. 5b, ejected light is shown as light 50a. The region of the concave portions 10 which is not covered by the first electrode 7 and open so as for laser light to be ejected to the outside is referred to as a surface emitting region 52, and the surface which is not covered by the first electrode 7 is an emitting surface 53.

With regard to light traveling in this surface emitting region 52 in the −y direction, since carriers are hardly injected into the active layer 3 and then just a small amount of light is generated in the active layer 3, diffraction to the outside and also diffraction in the +y direction occur, resulting in the monotonic decrease of light Thereby, as separation from the border of the first electrode 7 and the emitting surface 53 (the border of the resonator region 51 and the surface emitting region 52) to the direction of the emitting surface 53 (the −y direction, the direction of the surface emitting region 52) is made, the optical intensity ejected to the outside is exponentially decreased.

Therefore, as shown in FIG. 5b, the optical intensity I ejected from the emitting surface 53 is maximized in the vicinity of the border of the first electrode 7 and the emitting surface 53 and the slope decreasing toward the −y direction comes to have an exponential shape, having a thickness of the width Wp in the x direction. This optical intensity distribution is a preferable intensity distribution of light irradiated to the coupler 29 to be efficiently introduced into the waveguide 20A.

Incidentally, the border of the emitting surface 53 and the first electrode 7 is preferably in the direction almost at right angles to the long side direction of the reed shape, since the waveguide 20A and the light source 70A are easily arranged.

In such a manner, the optical intensity distribution of light emitted from the light source 70A has a shape almost homothetic to an optical intensity distribution such that light is efficiently introduced into the waveguide 20A and thereby the introduction efficiency of light into the waveguide determined by the product of the overlapping portions of both can be increased. To further increase the introduction efficiency, the optical intensity distribution shapes of the light source 70 of the side of light irradiation and the waveguide 20 of the side where light is irradiated to be introduced are preferably overlapped. Therefor, coupling coefficients κ representing the efficiency of a grating need to be equal. Coupling coefficient κ can be set based on the depth of the grating, aspect ratio, and refractive index difference via designing. Therefore, the grating of the waveguide 20 and the two-dimensional photonic crystal structure are preferably designed so as for the coupling coefficients κ of the light source 70 and the waveguide 20 to accord.

Incidentally, the emitting surface 53 may be provided with a transparent electrode such as, for example, ITO (Indium Tin Oxide) to increase the optical intensity distribution of laser light ejected from the emitting surface 53 as described above. When the resonator region 51 and the surface emitting region 52 have the same structure, no electrical current is injected into the surface emitting region 52, which becomes an absorption region, whereby the threshold of laser emission is increased. Therefor, to eliminate absorption loss by allowing the band gap of the surface emitting region 52 to have short-wavelength, quantum-well intermixing (QWM) is preferably employed.

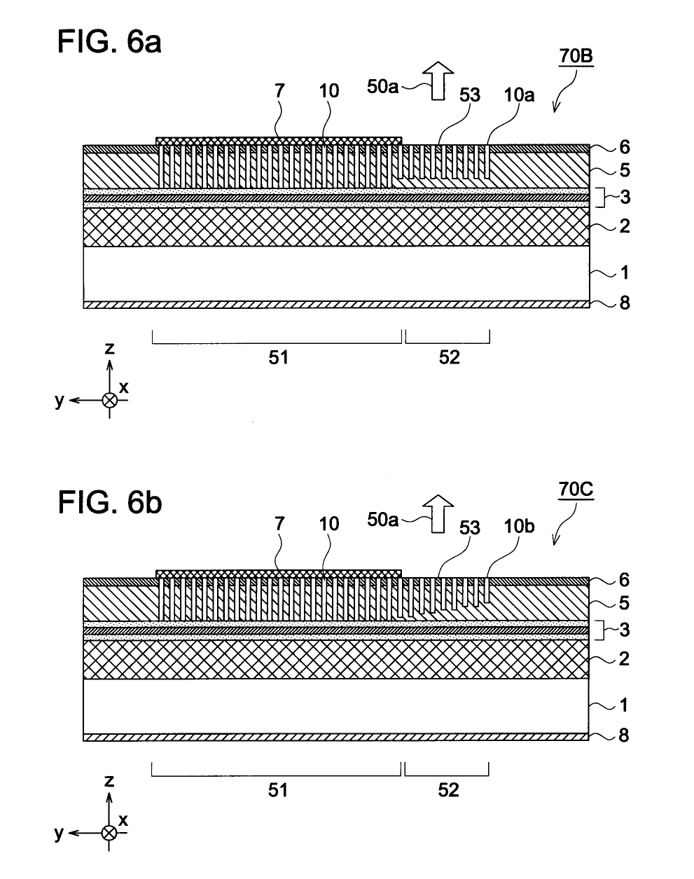

Further, the depths of the concave portions 10 of the resonator region 51 and the surface emitting region 51 may be differ. For example, as in the light source 70B shown in FIG. 6a, with respect to the depth of the concave portions 10 of the resonator region 51, the bottom of the concave portions 10 is allowed to be close to the active layer 3 so that the optical coupling of the active layer 3 and the two-dimensional photonic crystal structure is further increased, and the depth of the concave portions 10 of the surface emitting region 52 is allowed to be smaller than in the concave portions 10 of the resonator region 51. Alternatively, as in the light source 70C shown in FIG. 6b, when the bonder of the first electrode 7 and the emitting surface 53 is designated as the starting point; the depth of the concave portions 10 of the surface emitting region 52 may be decreased with separation from the border to the direction of the emitting direction 53 side (the −y direction).

In this manner, optical coupling efficiency is changed and thereby the decease state from the maximum of the optical intensity I ejected from the emitting surface 53 is adjusted. Thereby, the intensity distribution shape of light emitted from the emitting surface 53 can be further fitted into an optimum shape of the optical intensity distribution to irradiate the coupler 29. Incidentally, in the concave portions 10 shown in FIG. 4 and FIG. 5b, the bottom thereof is located at a position immediately before reaching the active layer 3, and the depths of the concave portions 10 in the resonator region 51 and the surface emitting region 52 are allowed to the same. The location of the bottom of the concave portions 10 needs not always to be at a position immediately before reaching the active layer 3, and needs only to be appropriately determined in view of adverse effects such as damage to the active layer 3 during concave portion 10 formation and the optical coupling efficiency of the active layer 3 and the two-dimensional photonic crystal structure.

Further, in the above description, in the method of changing the optical coupling of the active layer 3 and the two-dimensional photonic crystal structure in the resonator region 51 and the surface emitting region 52, the depths of the concave portions 10 are allowed to differ. However, the cross-sections of the depth direction may be allowed to be constant, for example, as in concave portions 10 having a columnar shape to change the cross-section areas thereof. For example, when the refractive index of a material filling the concave portions 10 is smaller than that of the first clad layer 5 in the periphery thereof, the cross-section area is allowed to be decreased to enhance coupling efficiency. Incidentally, in the method of changing the optical coupling of the active layer 3 and the two-dimensional photonic crystal structure, the depth and the cross-section area of the concave portions 10 have been cited. However, these may be employed individually or in combination.

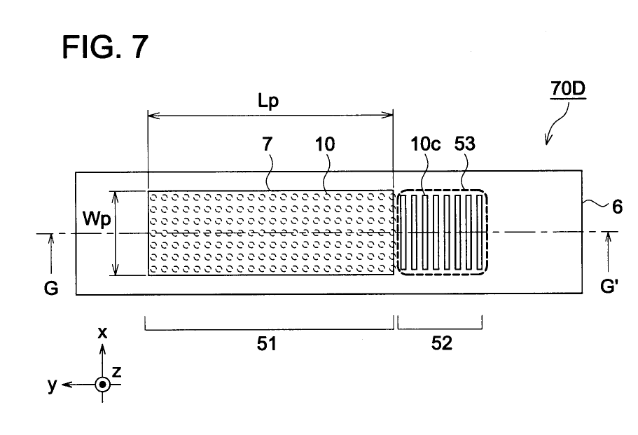

In the photonic crystal structure of the surface emitting region 52, a parallel arrangement of striped groove-shaped concave portions 10 is employable as in the light source 70D shown in FIG. 7, instead of the grid point arrangement described above. Since the photonic crystal structure of the resonator region 51 is two-dimensional, laser light is oscillated in the single mode and width Wp is ensured. Then, laser light having been oscillated and amplified with this width Wp reaches the surface emitting region 52 to eject laser light having an optical intensity distribution as described so far from the emitting surface 53. Incidentally, FIG. 7 shows only a top view of the light source 70D and its cross-sectional view is omitted due to the similarity to FIG. 5b and FIGS. 6a and 6b. The depth of the concave portions 10 may be the same as in the resonator region 51 or relatively small.

Laser light injected into the coupler 29 of the waveguide 20 having been described so far is nearly vertical to the coupler 29 surface but occasionally required to enter at a predetermined incident angle. In this case, to match the incident angle to the coupler 29 of the waveguide 20, a countermeasure can be taken in such a manner that with no change of the posture of the light source 70, laser light allowed to have an ejection angle inclined from the vertical direction (normal line) to the emitting surface 53 is ejected.

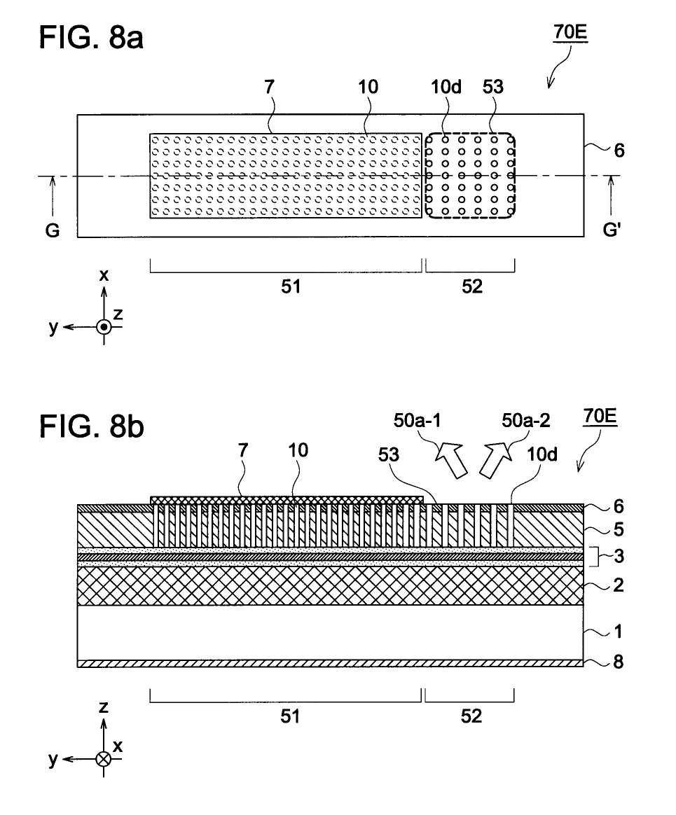

To provide the ejection angle of laser light ejected from the emitting surface 53, in the two-dimensional photonic crystal structure, the period of the surface emitting region 52 is allowed to differ from that of the resonator region 51. This example is shown in the light source 70E of FIGS. 8a and 8b. FIG. 8a is a top view of the light source 70E and FIG. 8b is a cross-sectional view taken along the line G-G′ of FIG. 8a.

In the surface emitting region 52, the period of the x direction of concave portions 10d is the same as in the resonator region 51 and the period of the y direction is longer than in the resonator region 51. When the period of they direction is changed in this manner, as shown in FIG. 8b, laser light ejected from the emitting surface 53 can be polarized, as ±primary diffraction lights, with ejection angles of the y-z in-plane direction in 2 directions of the +y direction (light 50a-1) and the −y direction (light 50a-2). The period of they direction needs only to be appropriately changed to match the incident angle to the coupler 29 of the waveguide 20. In the surface emitting region 52 shown in FIGS. 8a and 8b, the period of the y direction of the concave portions 10d is allowed to be longer than in the resonator region 51 with no limitation thereto and may be shorter since the periods need only to differ from each other. Herein, when the period of the x direction of the concave portions 10d is further changed, the ejection angle in z-x plane can be changed. Thereby, light ejected from the emitting surface 53 becomes in 4 directions of the directions in addition to the ±y directions.

As shown in FIG. 8a, the concave portions 10d of the surface emitting region 52 are arranged as grid points. However, as shown in FIG. 7, the concave portions 10d of the surface emitting region 52 are formed into striped groove-shaped concave portions, and then the period of the y-direction needs only to differ from the period in the resonator region 51 as described above, being possibly relatively long or short.

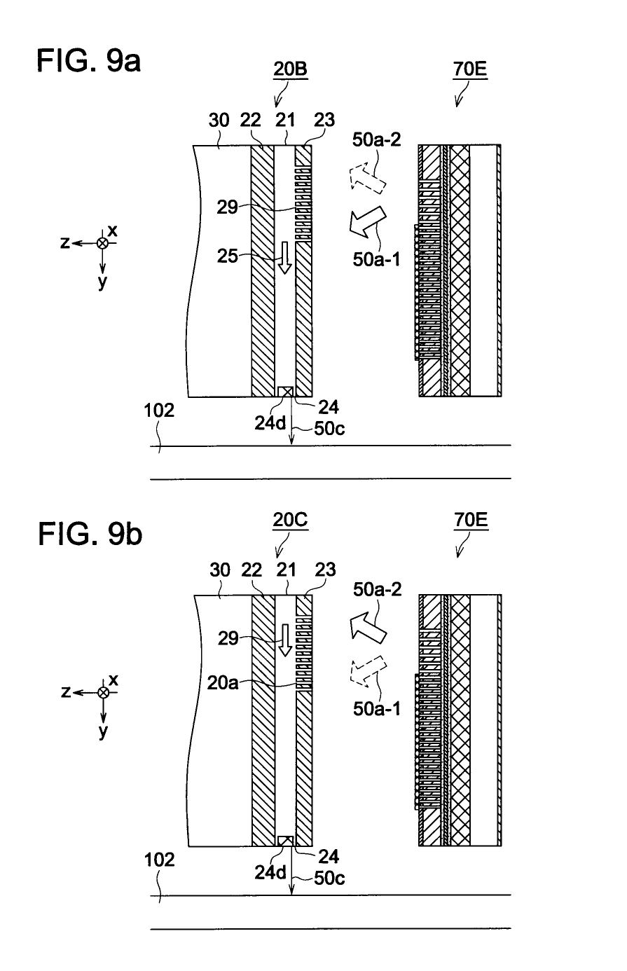

An example of combination of a light source 70E to eject laser light inclined from the direction vertical to the emitting surface 53 and a waveguide 20 is shown in FIGS. 9a and 9b. In FIG. 9a, of laser lights of 2 directions ejected flow the light source 70E, a combination of a waveguide 20B enabling to efficiently introduce laser light 50a-1 ejected in the downward direction (the −y direction) and the light source 70E is shown. In this case, laser light 50a-2 is hardly introduced into the waveguide 20B. In FIG. 9a, of the laser lights of 2 directions ejected from the light source 70E, a combination of a waveguide 20C enabling to efficiently introduce laser light 50a-2 ejected in the upward direction (the +y direction) and the light source 70E is shown. In this case, laser light 50a-1 is hardly introduced into the waveguide 20B.

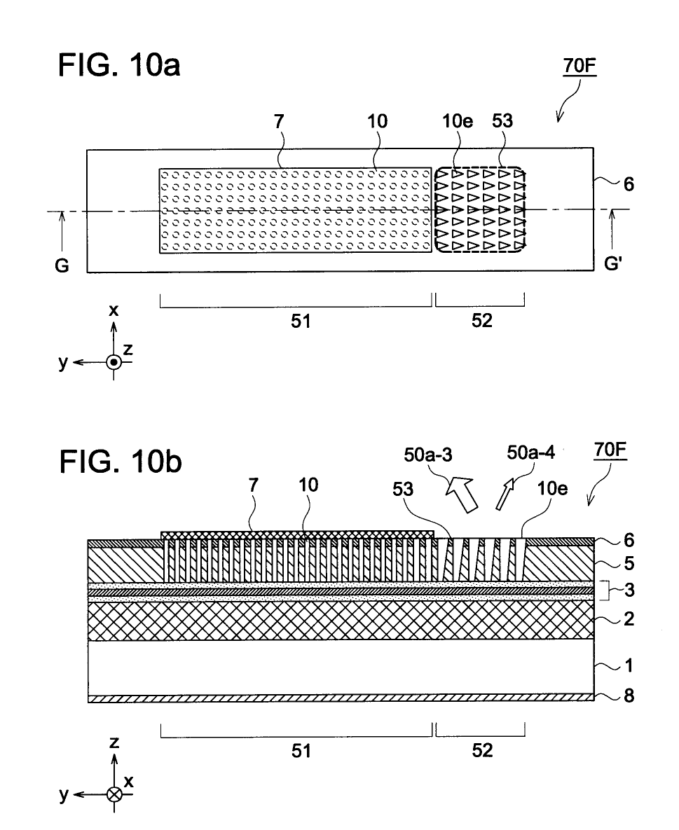

As shown and described in FIGS. 8a and 8b, the period of the y direction of the concave portions 10d of the surface emitting region 52 is allowed to differ from that of the resonator region 51, and thereby laser light inclined from the vertical direction to the emitting surface 53 is ejected in 2 directions with almost the same intensity. As shown and described in FIGS. 9a and 9b, one of the laser lights having been ejected in the 2 directions does not enter the coupler 29 to be introduced into the waveguide 20, resulting in loss. To decrease this loss, when the ejection angle of laser light is inclined out the vertical direction to the emitting surface 53, of the 2 directions ejected from the light source 70, one optical intensity is preferably allowed to be larger than that of other one, and this specific example is shown in the light source 70F of FIGS. 10a and 10b. FIG. 10a is a top view of the light source 70F and FIG. 10b is a cross-sectional view taken along the line G-G′ of FIG. 10a.

As shown in FIG. 10b, in the cross-sectional shape (a cross-sectional view taken along the line G-G′) of the y-z surface of a concave portion 10e, the widths of the concave portion 10e of the emitting surface 53 side and the active layer 3 side are allowed to differ and also a wedge shape is formed to be asymmetrical to the x axis. In the concave portion 10e of FIG. 10b, the border of the left side (the +y direction) is almost vertical to the main surface but the border of the right side (they direction) is inclined toward the paper plane clockwise.

When such an asymmetrical shape is formed with respect to the z axis in x-y plane in this manner, the intensity of one of ±primary diffraction lights obliquely ejected from the emitting surface 53 can be allowed to be larger than the intensity of the other one. The determination which intensity is allowed to be larger, in the +y direction or in the −y direction is allowed to depend on the specifications of the waveguide 20 into which laser light is introduced, as shown in the waveguides 20B and 20C shown in FIG. 9.

In FIG. 9a, instead of the light source 70E, the light source 70F is combined with the wave guide 20B and thereby the light source 70F can introduce laser light into the waveguide 20B more efficiently than the light source 70E. Further, in responding to the waveguide 20C, the wedge shape of the concave portion in FIG. 10b is formed in a left-right (y-direction) reversal manner. Still further, using the above-described asymmetry, the intensity of one of the ±primary diffraction lights is allowed to be larger than the optical intensity of the other one and in addition, the optical intensity of one of the diffraction lights in the upward direction (the +z direction) and the downward direction (the −z direction) can be allowed to be larger than the optical intensity of the other one. In the example of FIG. 10b, the optical intensity of the +z direction is smaller than that of the −z direction.

As shown in FIG. 10a, the cross-sectional shape (the opening cross-sectional shape) of the vertical direction to the depth direction of the concave portion 10e is allowed to have a triangle with no limitation, including also a square and an ellipse.

In the photonic crystal structure of the surface emitting region 52, to efficiently introduce laser light into a waveguide 20 as the target to be irradiated with laser light, the depth of the concave portion 10, the striped groove-shaped concave portion, the period change of they direction, and wedge-shape formation of the cross-sectional shape of the concave portion, having been described so far, may be employed individually or in combination.

As in the waveguide 20 and the light source 70, having been described so far, shown in FIG. 4, the coupler 29 of the waveguide 20A and the emitting surface 53 of the light source 70A are arranged facing each other and fixed. As shown in FIG. 4, an arrangement is preferably made so that light 50a ejected from the lower end portion of the emitting surface 53 enters the lower end portion of the coupler 29. For more detail, it is preferable that the maximum portion of the intensity distribution of laser light ejected from the emitting surface 53 irradiate the tip portion of the traveling direction of light having been introduced into the core layer 21 in the light irradiation region of the coupler 29 to introduce light into the core layer 21.

The waveguide 20 and the light source 70 can be fixed using, for example, an adhesive. As the adhesive, any appropriate polyimide-based UV curable or thermally curable resin is used with no limitation if light of the light source 70 is transmitted therethrough. Further, the refractive index of the above resin is preferably the same as or close to those of materials forming the coupler 29 and the emitting surface 53 from the viewpoint of reducing light loss. Still further, in order to prevent the reflection of light while light from the light source 70 is introduced into the waveguide 20 via the adhesive, the refractive index and the thickness of the adhesive may be adjusted.

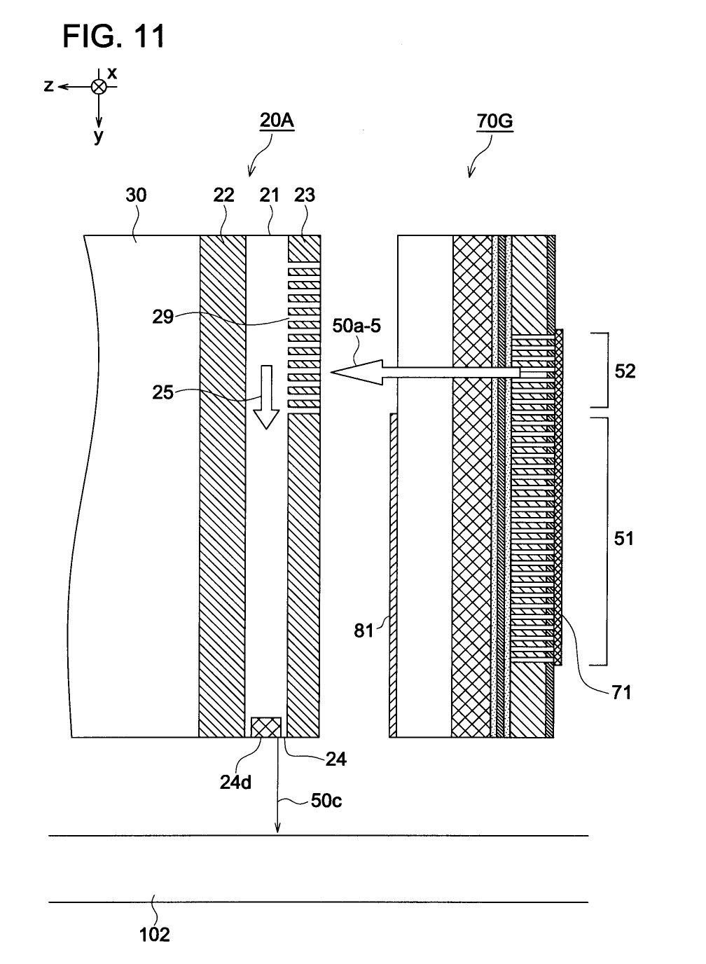

In the present embodiments having been described so far, the upper surface of the first clad layer 5 is allowed to be the ejection surface (the emitting surface 53) to eject laser light. However, the second electrode 8 side can be allowed to be the emitting surface and an example thereof is shown as the light source 70G of FIG. 11.

In the light source 70G, the substrate 1 is a material transparent with respect to the wavelength band of light to be taken out and a first electrode 71 is formed on a contact layer 6 to cover the entire two-dimensional crystal structure and then in a second electrode 81, an opening is formed. For example, there are an InP substrate for an InGaAsP-based active layer (wavelength: 1.3 μm-1.5 μm), a GaAs substrate for an InGaAs-based active layer (wavelength: 0.9 μm-1.1 μm), and a GaN or sapphire substrate for an InGaN-based active layer (wavelength: 0.4 μm-0.5 μm). Herein, the first electrode 71 and the second electrode 81 are formed of materials through which light to be taken out is not transmitted.

Detailed description of the light source 70G will be omitted, since describable in the same manner as the light source 70A having been described with reference to FIGS. 5a and 5b. The second electrode 81 is formed of a material through which light resonated in the two-dimensional photonic crystal structure is not transmitted, and formed so as to cover other portions except the end portion on the side of the short side of the reed shape in the two-dimensional photonic crystal structure. Therefore, the region located between the first electrode 71 and the second electrode 81 of the two-dimensional photonic crystal structure is a resonator region 51. The region of the concave portions 10 not covered by the second electrode 81 and open so as to able to eject laser light to the outside is a surface emitting region 52.

In the substrate 1, when viewed from the direction of laser light ejection, the region not covered by the second electrode 81 of the end portion on the side of the short side of the reed shape in the two-dimensional photonic crystal structure is the emitting surface. Incidentally, also in this case, in the same manner as in the described case in the light source 70A, a transparent electrode may be provided for the emitting surface.

Further, in the photonic crystal structure of the surface emitting region 52 of the light source 70G, to efficiently introduce laser light into the waveguide as the target of laser light ejection, the change of the depth of the concave portion, the striped groove-shaped concave portion, the period change of the y direction, and wedge-shape formation of the cross-sectional shape of the concave portion, having been described so far, may be introduced individually or in combination.

The light source 70 having been described so far is provided with the first electrode 7 and the second electrode 8, being a surface emitting semiconductor laser to emit laser light via electrical current injection by these electrodes. However, a surface emitting semiconductor laser to emit laser light via photoexcitation instead of electrical current injection can also be formed. A surface emitting semiconductor laser employing photoexcitation and an optical recording head provided with this laser will now be described. Incidentally, the same portions and equivalent portions with respect to the light source 70 and the optical recording head 103 provided with the light source 70 are assigned with the same symbols to appropriately omit overlapping description.

FIG. 13 schematically shows an optical recording head 103 according to the present invention and its periphery using a cross-section. The optical recording head 103 is an optical recording head employing light in information recording on a disk 102, having a slider 30, a waveguide 20, a light source 80, a magnetic recording section 35, and a magnetic information regeneration section 36.

In the optical recording head 103, the light source 80 (a laser) to introduce laser light into the waveguide 20 will be described as a surface emitting semiconductor laser later, being able to be an organic dye laser or a solid laser other than the semiconductor laser.

In the slider 30, on the side of the inflow side of the disk 102 almost vertical to the recording surface of the disk 102, the waveguide 20 and the light source 80 are provided.

The light source 80 is a surface emitting semiconductor laser provided with a two-dimensional photonic crystal structure in the same manner as in the light source 70, and to introduce light into the waveguide 20, light is irradiated to the grating coupler. Further, the light source 80 is a photoexcitation type in which excitation light 110a from a photoexcitation source 110 as another light source is irradiated to the light source 80 to generate laser light. Herein, the excitation light 110a is irradiated to the two-dimensional photonic crystal structure of the light source 80.

On the side of the slider 30, the thin plate-shaped waveguide 20 and the light source 80 enabling to carry out surface emission are provided in a layered manner and thereby the optical recording head 103 can be downsized and thinner.

The photoexcitation source 110 emits light to irradiate the light source 80 for photoexcitation. As the light source 80, for example, another semiconductor laser and an optical fiber ejection end portion are listed. In FIG. 13, the photoexcitation source 110 is a semiconductor laser and is fixed to an arm 105 together with a lens 112 provided with a plurality of lenses to allow light ejected from the semiconductor laser to be nearly parallel light or converging light to adequately irradiate a two-dimensional photonic crystal structure preferably provided with the light source 80.

Light having been ejected from the light source 80 is introduced into the waveguide 20 and the light having been introduced into the waveguide 20 is moved to the lower end surface 24 of the waveguide 20 to be ejected toward the disk 102 as irradiation light to heat the disk 102. Herein, in FIG. 13, a plasmon antenna 24d provided in the location where light of the lower end surface 24 is ejected or in the vicinity thereof is omitted.

The waveguide 20 of FIG. 13 shows the waveguides 20A-20C of the examples having been described so far. The light source 80 shows light sources 80A-80H of examples, to be described later, for appropriate combinations with any of these waveguides.

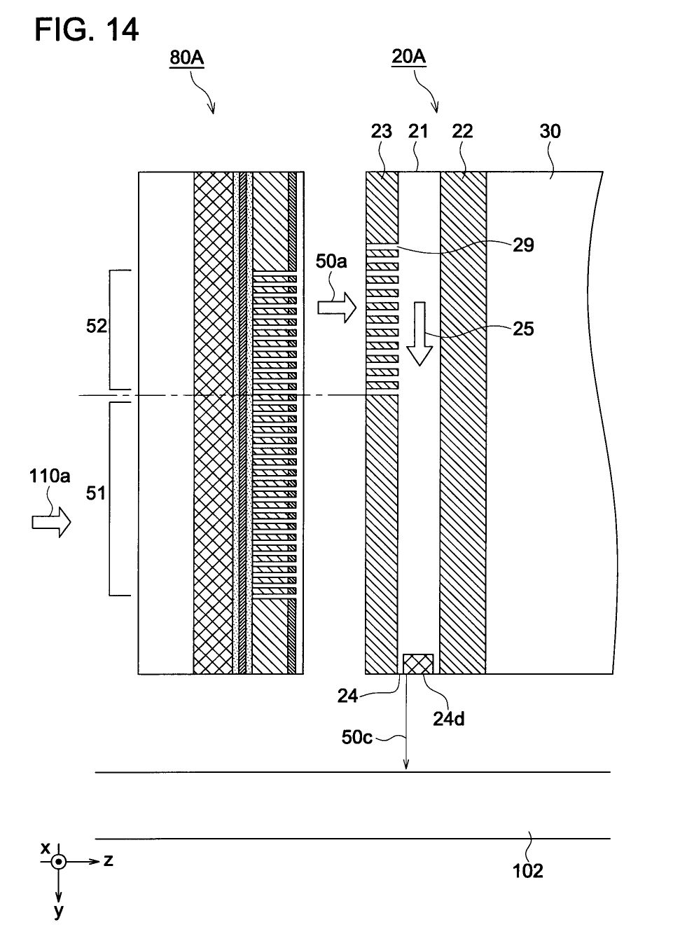

FIG. 14 simultaneously shows a waveguide 20A and a light source 80A to emit light introduced into the waveguide 20A. Light 50a ejected from the light source 80A is irradiated to the coupler 29 of the waveguide 20A.

The incident angle of light to irradiate the coupler 29 may be almost vertical (incident angle: 0°) to the waveguide 20 if appropriate or have any appropriate incident angle. In FIG. 14, an example in which the incident angle is allowed to be 0° is shown.

Before a light source 80B to emit light in which the optical intensity distribution to irradiate the coupler 29 has an exponential shape is described in the same manner as in the light source 70 having been described so far, the light source 80A carrying out surface emission via photoexcitation being a fundamental form of the light source 80B will now be described. FIG. 15a is a top view of the light source 80A and FIG. 15b is a cross-sectional view taken along the line G-G′ of FIG. 15a. The light source 80A is provided with a substrate 1, a second clad layer 2 formed on one main surface of the substrate 1, an active layer 3 formed on the second clad layer 2, a semiconductor laminated portion having a first clad layer 5 formed on the active layer 3 and a contact layer 6, and a two-dimensional photonic crystal structure to specify the wavelength of laser light emitted via optical coupling with the active layer 3.

In the light source 80A provided for the slider 30 of the optical recording head 103 shown in FIG. 13, excitation light 110a having been ejected from the photoexcitation source 110 arranged in the arm 105 is irradiated from the substrate 1 side. Irradiated excitation light 110a is transmitted through the substrate 1 to be absorbed in the active layer 3 of the light source 80A. Thereby, electron/positive hole pairs (carriers) are injected and then in the active layer 3, light is generated. Light having been generated in the active layer 3 leaks to the two-dimensional photonic crystal structure to be introduced thereinto for laser oscillation. Oscillated laser light is ejected in the vertical direction flout the emitting surface 53 as seen in light 50a. Thereby, in the light source 80A, no wiring flout the outside to inject electrical current is required or no Joule heat resulting from resistant components of the semiconductor laser is generated. Therefore, the movement of the optical recording head 103 is not restricted by wiring. Further, the optical recording head 103 is hardly thermally deformed. Accordingly, the optical recording head 103 can stably carry out optical recording.

Incidentally, the emitting surface 53 shown in FIG. 15 is wider than the coupler 29 as shown in FIG. 14. Light 50a not to be irradiated to the coupler 29 results in loss, possibly producing an adverse effect on the outside. Therefor, part of the emitting surface 53 is preferably covered to shield light not to be irradiated to the coupler 29.

The wavelength of excitation light 110a emitted from the photoexcitation source 110 needs only to be wavelength absorbed by the active layer 3. For example, when the wavelength via laser oscillation of the light source 80A is 980 nm, the wavelength of excitation light 110a needs only to be wavelength shorter than a wavelength of 980 nm for laser oscillation of 780 nm. However, as shown in FIG. 15, since excitation light 110a is irradiated from the substrate 1 side, the substrate 1 is required to be transparent with respect to the excitation light 110a. In the case where the substrate 1 described below is a GaAs substrate, excitation light 110a needs to have wavelength transmittable through the GaAs substrate and this wavelength needs to be larger than 870 nm and also to be smaller than 980 nm as described above.

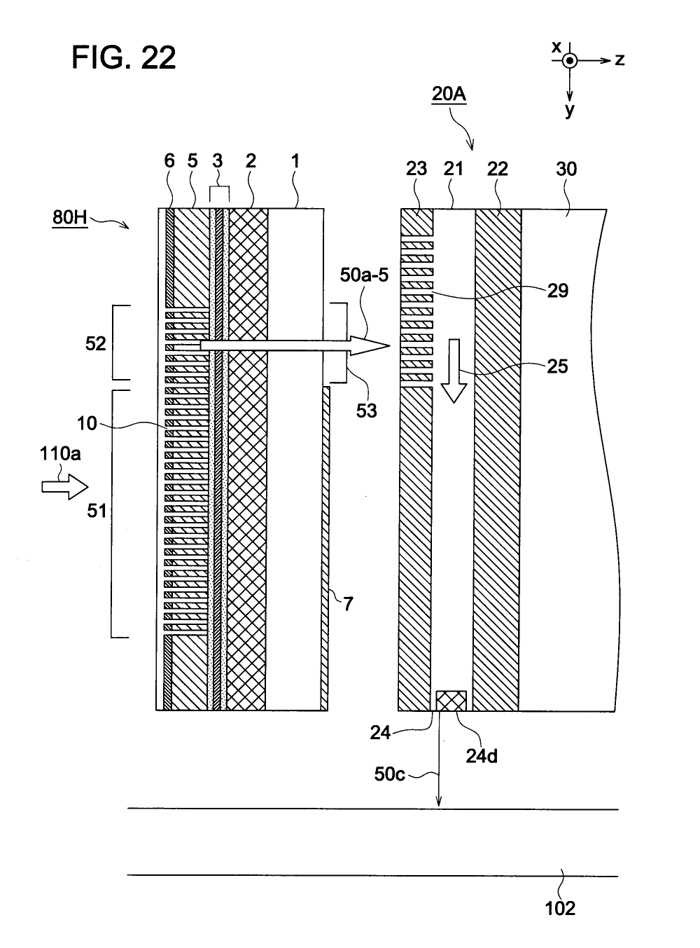

Incidentally, when excitation light 110a cannot be transmitted through the substrate 1, a countermeasure can be taken by forming a light source 80H to be described later with reference to FIG. 22.

The constitution of the light source 80 is almost the same as in the light source 70 and then main points differing from the light source 70 relevant to photoexcitation will now be described.

In the active layer 3, the following consideration needs to be taken into account in addition to description of the light source 70. When as the active layer 3, a material system featuring wavelength larger than that of the substrate 1 (for example, an InGaAsP-based active layer on an InP substrate, wavelength: 1.3 μm-1.5 μm, an InGaAs-based active layer on a GaAs substrate, wavelength: 0.9 μm-1.1 μm, or an InGaN-based active layer on a GaN or sapphire substrate, wavelength: 0.4 μm-0.5 μm) is used, the substrate 1 is transparent with respect to the emission wavelength (also being the absorption wavelength) of the active layer 3. Thereby, the light source 80A shown in FIGS. 14 and 15 can allow excitation light 110a to enter from the substrate 1 side.

In the present embodiments, a contact layer 6 is provided, but may not be provided due to employment of photoexcitation.

As shown in FIG. 15a, when viewed from the contact layer 6 side, the region where concave portions 10 are formed has a reed shape of width Wp and length Lp1. The width Wp can provide the emission region with width. In the case where the width direction (the x direction) of the coupler 29 of, for example, about 50 μm can be thoroughly irradiated, the width Wp is preferably at least the width (the x direction) of the coupler 29 and the length LP1 is preferably at least the length where laser oscillation and oscillation wavelength are stabilized. In the same manner as in the light source 70, of lights having leaked from the active layer 3 and than having been introduced into the two-dimensional photonic crystal structure, light having wavelength according with the periodic distance of the concave portions 10 in this reed shape is oscillated and then amplified for laser oscillation to be ejected to the outside as coherent laser light from the emitting surface 53 of the reed shape in the vertical direction.

In the light source 80A, laser light having been generated via photoexcitation is ejected from the emitting surface 53 of the reed shape almost in the vertical direction via the two-dimensional photonic crystal structure provided by forming concave portions 10 in the first clad layer 5 to be introduced into the waveguide 20A via the coupler 29 to be irradiated.

Excitation light 110a preferably irradiates a region except the region to eject light to irradiate the coupler 29 in the two-dimensional photonic crystal structure. When the excitation light 110a irradiates the region to eject light to irradiate the coupler 29, part of the excitation light 110a enters the coupler 29 and thereby noise may be generated. The region where excitation light 110a irradiates the two-dimensional photonic crystal structure and the region to eject light to irradiate the coupler 29 are shown in FIG. 14 as a resonator region 51 and an emitting region 52, respectively.

The light source 80A can preferably oscillate laser light of constant wavelength with no adverse effect even when the wavelength of excitation light 110a varies due to a change in operation ambience temperature as in a mode hop phenomenon produced in a Fabry-Perot-type laser. Further, the light source 80A can preferably carry out laser oscillation when a region where a photonic crystal is formed is roughly irradiated with excitation light 110a. Thereby, even with the location shift or the incident angle change of excitation light 110a to irradiate the light source 80A, the light source 80A is hardly affected and then laser oscillation can be preferably carried out

In this manner, with respect to the irradiation location, the incident angle, and the wavelength during irradiation of the light source 80A with excitation light 110a, the allowances of these errors are large, compared with the case of irradiation of the coupler 29 provided for the waveguide 20 using the light source 80A.

Therefore, in the optical recording head 103 of FIG. 13, when a waveguide 20 and a light source 80A are integrally provided for the slider 30, the locational relationship between the photoexcitation source 110 and the optical recording head 103 can be easily adjusted. Further, in an actual optical recording operation, location shifting exceeding the allowable error in the above locational relationship can be prevented from easily occurring. Therefore, the optical recording head 103 can stably carry out optical recording.

Incidentally, as the power density of excitation light 110a is increased, oscillation is easy to occur. Therefore, excitation light 110a is preferably irradiated so as to be collected at the region where a two-dimensional photonic crystal structure is formed. In FIG. 13, to collect excitation light 110a, a lens 112 as a collecting lens is arranged on the way of the light path. However, for example, a curved surface or a diffraction grating may be formed in the substrate 1 of FIG. 15 to provide a collecting function.

Description will now be made with respect to the light source 80B in which the slope where the optical intensity distribution of laser light emitted from the light source 80 is efficiently introduced into the core layer 21 from the coupler 29 in the same manner as in the light source 70 is an exponential shape.

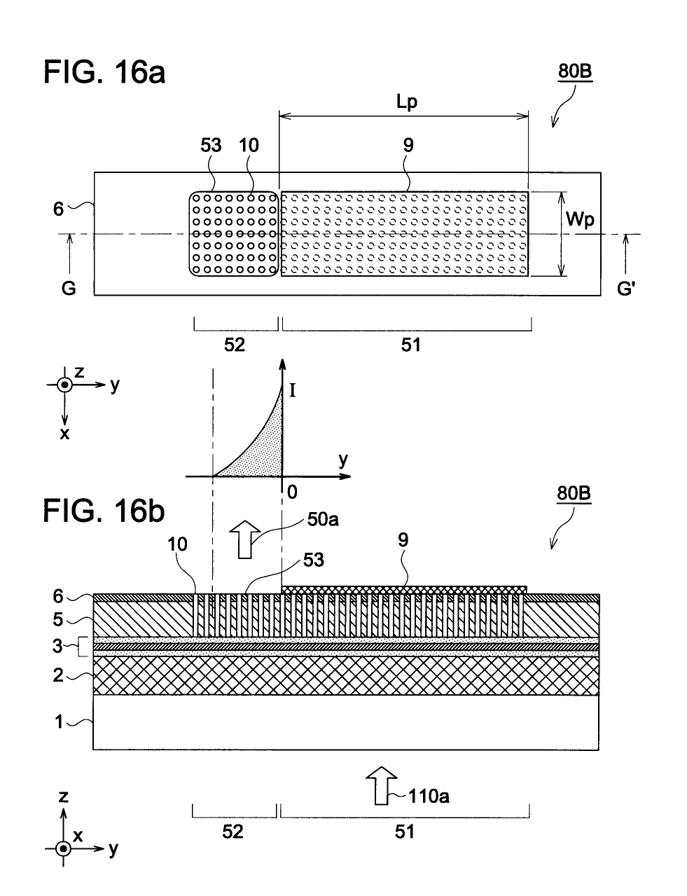

FIG. 16a is a top view of the light source 80B and FIG. 16b is a cross-sectional view taken along the line G-G′ of FIG. 5a. The light source 80B is provided with a substrate 1, a second clad layer 2 formed on one main surface of the substrate 1, an active layer 3 formed on the second clad layer 2, a semiconductor laminated portion having a first clad layer 5 formed on the active layer 3 and a contact layer 6, and a light shielding member 9 formed on the contact layer 6.

The light shielding member 9 is provided to cover part of the concave portions 10 forming a two-dimensional photonic crystal structure.

The light shielding member 9 is formed of a material through which light oscillated in the two-dimensional photonic crystal structure is not transmitted to cover, as shown in FIG. 16a, other portions except one end portion on the side of the short side of the reed shape in the region where the concave portions 10 are formed.

The region where the light shielding member 9 covets the concave portions 10 is preferably irradiated with excitation light 110a, being a resonator region 51 for laser oscillation. The location where excitation light 110a irradiates the resonator region 51 is a surface on the opposite side to the light shielding member 9 of the substrate 1 in FIG. 16 with no limitation thereto, being possibly the side surface side (the x direction side). Further, irradiation may be carried out from the light shielding member 9 side if excitation light 110a is transmitted therethrough. Namely, the location irradiated with excitation light 110a may be anywhere in the periphery of the resonator region 51.

In the resonator region 51, electron/positive hole pairs (carriers) having been generated by excitation light 110a which is transmitted through the substrate 1 to enter are injected into the active layer 3, and in the active layer 3, light is generated. Thus-generated light in the active layer 3 leaks to the two-dimensional photonic crystal structure to be introduced fix laser oscillation.

In the resonator region 51, width Wp is preferably at least the width of the coupler 29 so as to thoroughly irradiate the width direction (the x direction) of the coupler 29. Length Lp is preferably at least the length where laser oscillation and oscillation wavelength are stabilized.

Light having been oscillated in the resonator region 51 can travel in the −y direction (a first direction) in the two-dimensional photonic crystal structure. Light having reached the region, not covered by the light shielding member 9 (the two-dimensional photonic crystal structure is open), is ejected, as coherent laser light, to the outside from the emitting surface 53. In FIG. 16b, laser light ejected to the outside from the emitting surface 53 is shown as light 50a. The region of the concave portions 10 which is not covered by the light shielding member 9 and open so as for laser light to be ejected to the outside is a surface emitting region 52, and the surface which is not covered by the light shielding member 9 is an emitting surface 53.

With regard to light traveling in this surface emitting region 52 in the −y direction, since no photoexcitation is generated due to no irradiation by excitation light 110a and then just a small amount of light is generated in the active layer 3, diffraction to the outside and also diffraction in the +y direction occur, resulting in the monotonic decrease of light. Thereby, as separation from the border of the light shielding member 9 and the emitting surface 53 (the border of the resonator region 51 and the surface emitting region 52) to the direction of the emitting surface 53 (the −y direction, the direction of the surface emitting region 52) is made, the optical intensity ejected to the outside is exponentially decreased.

Therefore, as shown in FIG. 16b, the optical intensity I ejected from the emitting surface 53 is maximized in the vicinity of the border of the light shielding member 9 and the emitting surface 53 and the slope decreasing toward the −y direction comes to have an exponential shape, having a thickness of the width Wp in the x direction. This optical intensity distribution is a preferable intensity distribution of light irradiated to the coupler 29 to be efficiently introduced into the waveguide 20.

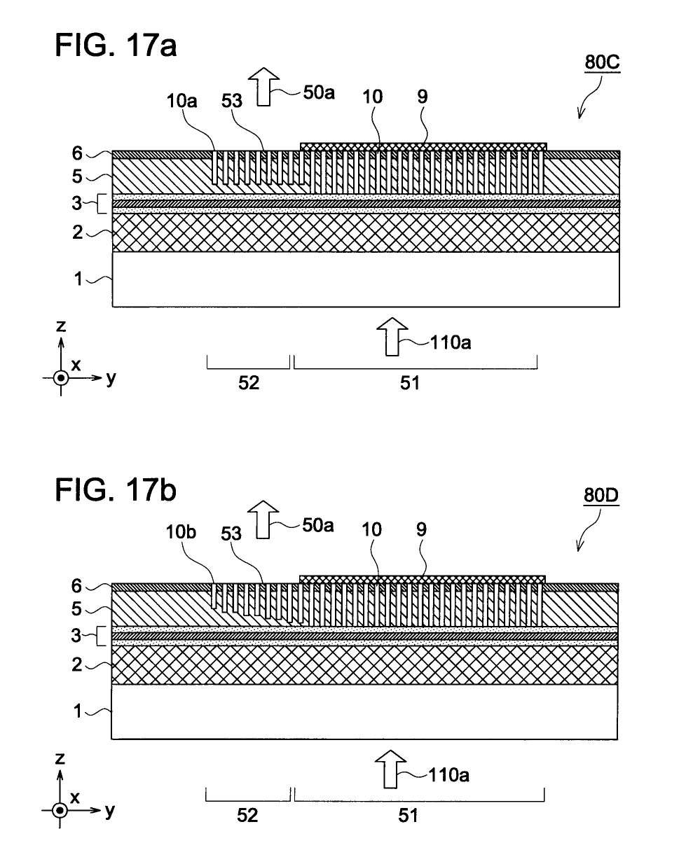

As shown in the light sources 80C and 80D of FIGS. 17a and 17b, the depths of the concave portions 10 of the resonator region 51 and the surface emitting region 52 may differ, which is the same as in the light sources 70B and 70C of FIGS. 6a and 6b. Therefore, description thereon will be omitted.

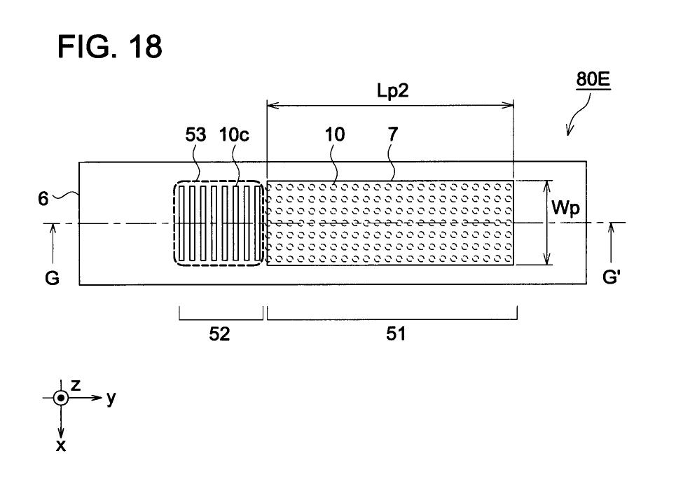

Instead of the grid point arrangement of the concave portions 10 in the photonic crystal structure of the surface emitting region 52 as shown in FIG. 16a, as in the light source 80E shown in FIG. 18, a parallel arrangement of striped groove-shaped concave portions 10 is employable. This is the same as in the light source 70D of FIG. 7 and therefore description will be omitted.

To match the incident angle to the coupler 29 of the waveguide 20, a countermeasure can be taken in such a manner that with no change of the posture of the light source 80, laser light allowed to have an ejection angle inclined from the vertical direction (normal line) to the emitting surface 53 is ejected.

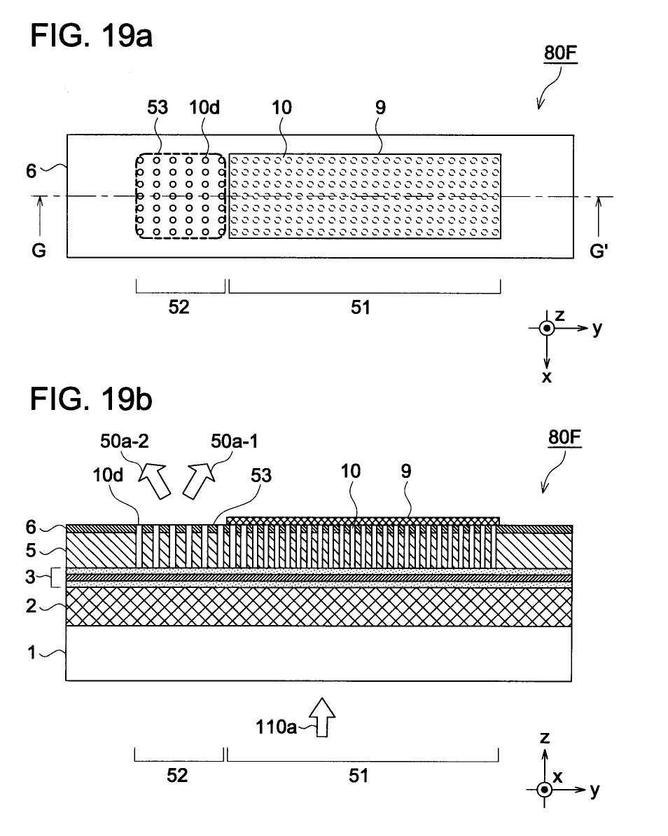

To provide the ejection angle of laser light ejected from the emitting surface 53, in the two-dimensional photonic crystal structure, the period of the surface emitting region 52 is allowed to differ from that of the resonator region 51. This example is shown in the light source 80F of FIGS. 19a and 19b. FIG. 19a is a top view of the light source 80F and FIG. 19b is a cross-sectional view taken along the line G-G′ of FIG. 19a, which is the same as in the light source 70E of FIGS. 8a and 8b and therefore description will be omitted.

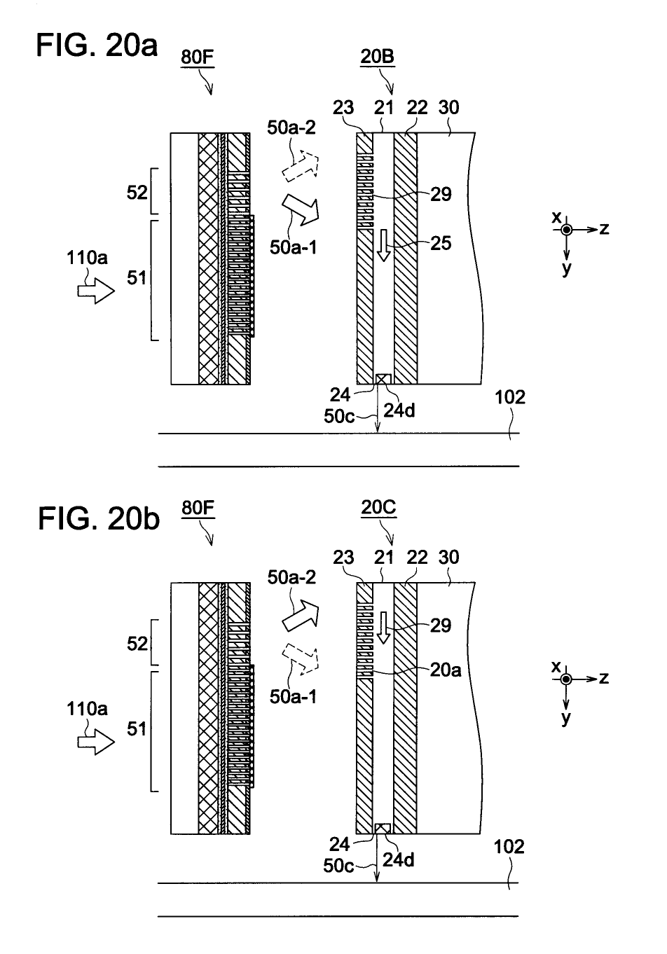

An example of combination of the light source 80F to eject laser light with an inclination from the normal line of the emitting surface 53 and the waveguide 20 is shown in FIGS. 20a and 20b, which is the same as the matter described in combination of the light source 70E and the waveguides 20B and 20C in FIG. 9. Therefore, description thereon will be omitted.

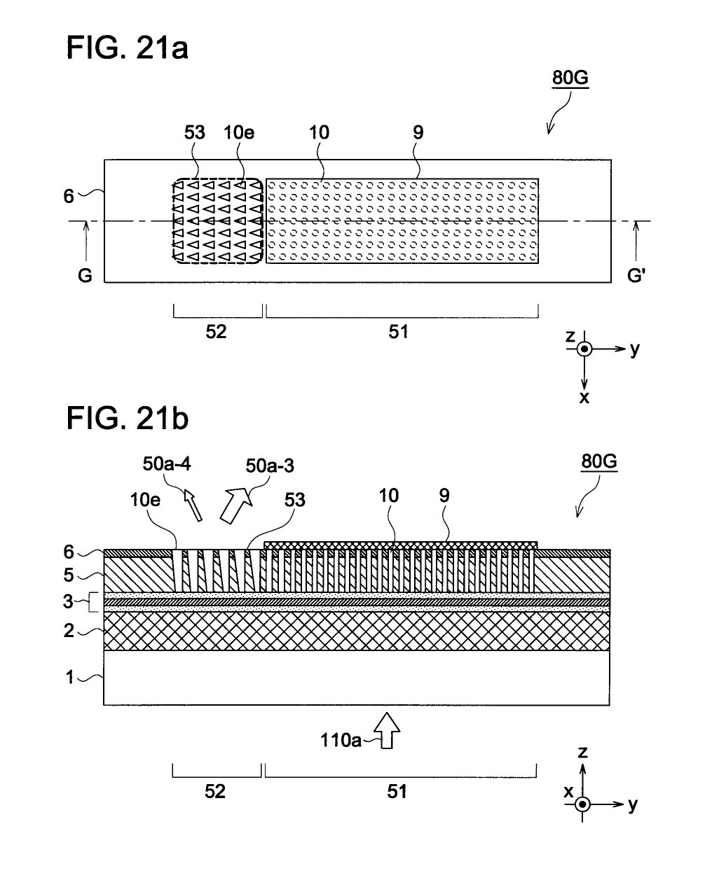

As shown in FIGS. 20a and 20b, one of the laser lights having been ejected in 2 directions does not enter the coupler 29 so as to be introduced into the waveguide 20, resulting in loss. To reduce this loss, when the ejection angle of laser light is inclined from the vertical direction to the emitting surface 53, of the 2 directions ejected from the light source 80, the optical intensity of one direction is preferably larger than that of the other one. This example is shown as the light source 80G of FIGS. 21a and 21b. FIG. 21a is a top view of the light source 80G and FIG. 21b is a cross-sectional view taken along the line G-G′ of FIG. 21a. This is the same as in the light source 70F of FIGS. 10a and 10b. Therefore, description thereon will be omitted.

In the photonic crystal structure of the surface emitting region 52 in the light source 80, in the same manner as in the light source 70, to efficiently introduce laser light into the waveguide 20 as the target of laser light irradiation, the depth of the concave portion 10, the striped groove-shaped concave portion, the period change of the y direction, and wedge-shape formation of the cross-sectional shape of the concave portion may be employed individually or in combination.

Arrangement and fixing, as shown in FIG. 14, of the waveguide 20 and the light source 80 having been described so far are the same as in the case of the light source 70 and therefore description will be omitted.

The case where excitation light 110a cannot be transmitted through the substrate 1 will now be described. When the emitting wavelength of the active layer 3 is, for example, 980 nm and the wavelength of excitation light 110a is 780 nm, a GaAs substrate comes to be opaque and thereby no photoexcitation can occur via light irradiation from the substrate 1 as described above. In such a case, a constitution as in the light source 80H shown in FIG. 22 is employed

The light source 80H shown in FIG. 22 can be described in the same manner as the light source 80B having been described with reference to FIGS. 16a and 16b. Therefore, detailed description will be omitted. A light shielding member 9 is formed on the surface on the opposite side to the side where a second clad layer 2 of the substrate 1 is formed so as to cover other portions except the end portion on the side of the short side of the reed shape in the region where concave portions 10 forming a two-dimensional photonic crystal structure are formed.

The region of the concave portions 10 covered by the light shielding member 9 is preferably a region irradiated with excitation light 110a, being a resonator region 51 for laser-oscillation. The region not covered by the light shielding member 9 and open so as for laser light to be ejected to the outside is a surface emitting region 52, being the emitting surface 53 in the substrate 1.

Excitation light 110a of a wavelength of 780 nm is irradiated from the first clad layer 5 side and thereby the light source 80H is optically excited. Oscillated laser light of a wavelength of 980 nm is irradiated to the waveguide 20A through the GaAs substrate 1 able to be transmitted at a wavelength of 980 nm to be introduced thereinto.

In the light source 80H, in the photonic crystal structure of the surface emitting region 52, to efficiently introduce laser light into the waveguide as the target of laser light irradiation, the depth of the concave portion, the striped groove-shaped concave portion, the period change of they direction, and wedge-shape formation of the cross-sectional shape of the concave portion having been described so far may be introduced individually or in combination.

In the description having been made so far, a semiconductor laser employing a III-V group semiconductor as the material of the semiconductor laminated portion is exemplified. However, instead thereof, an organic emitting material or a solid dye material is also employable. For example, on a quartz substrate surface, a two-dimensional photonic crystal structure is formed and thereon, film formation is carried out via spin coating or deposition, whereby a laser (an organic dye laser) provided with a two-dimensional photonic crystal structure can be formed. Further, on the quartz substrate surface, a two-dimensional photonic crystal structure is formed and thereon, film formation is carried out via sputtering to form upper and lower clad layers, and then between the upper and lower clad layers, a solid dye is formed, whereby a laser (an organic dye laser) provided with a two-dimensional photonic crystal structure can be formed.

The embodiments having been described above relate to an optically assisted magnetic recording head and an optically assisted magnetic recording apparatus. The main part constitution of the embodiments can also be employed in an optical recording head used for an optical recording disk as the recording medium and an optical recording apparatus. In this case, the magnetic recording section 35 and the magnetic information regeneration section 36 provided for the slider 30 are not required.

### DESCRIPTION OF THE NUMERALS

1: substrate

2: second clad layer

3: active layer

5: first clad layer

6: contact layer

7, 71: first electrode

8, 81: second electrode

9: light shielding member

10, 10a, 10b, 10c, 10d, 10e: concave portion

20, 20A, 20B, 20C: waveguide

21: core layer

22: lower clad layer

23: upper clad layer

24: lower end surface

24d: plasmon antenna

26, 27: side

29: coupler

30: slider

50a, 50a-1, 50a-2, 50a-3, 50a-4, 50a-5: light

51: resonator region

52: surface emitting region

53: emitting surface

70, 70A-70G, 80, 80A-80H: light sources

100: optical recording apparatus

101: housing

102: disk

103: optical recording head

104: suspension

105: arm

110: photoexcitation source

110a: excitation light

Wp: width

Lp, Lp1: length

1-22. (canceled)

23. An optical recording head comprising:
a light source; and
a waveguide for irradiating a recording medium with light from the light source, the light being joined to the waveguide via a diffraction grating;
wherein the light source is a surface emitting laser in which a two-dimensional photonic crystal structure is provided in a surface on a side opposite to the waveguide, a region except a region opposite to the diffraction grating is covered in the two-dimensional photonic crystal structure, and the region opposite to the diffraction grating is a surface emitting region.

24. The optical recording head, described in claim 23, wherein the surface emitting laser is a surface emitting semiconductor laser in which a member to cover the two-dimensional photonic crystal structure is a first electrode to form a resonator region together with a second electrode opposite to the first electrode.

25. The optical recording head, described in claim 23, wherein the surface emitting laser, in which a member to cover the two-dimensional photonic crystal structure is a light shielding member, emits light by excitation light irradiated to a side opposite to a side where the light shielding member of the surface emitting laser is located.

26. The optical recording head, described in claim 23, wherein the light source is fixed to the waveguide.

27. The optical recording head, described in claim 25, wherein a photoexcitation source to emit excitation light to allow the surface emitting laser to emit light is provided and the surface emitting region is not irradiated with the excitation light.

28. The optical recording head, described in claim 23, wherein the recording medium is a magnetic recording medium and a slider moving relatively to the magnetic recording medium and having at least the light source, the waveguide, and a magnetic recording section is provided.

29. In a surface emitting semiconductor laser, arranged opposite to a waveguide having a grating coupler, to eject light to be introduced into the waveguide toward a grating coupler, the surface emitting semiconductor laser comprising:
a semiconductor laminated portion having a first clad layer, a second clad layer, and an active layer, sandwiched between the first clad layer and the second clad layer, to generate light of a predetermined wavelength by carrier injection;
a first electrode connected to the first clad layer; and
a second electrode connected to the second clad layer;
wherein the first clad layer is provided with a diffraction grating having a constitution in which refractive index is changed with a period corresponding to the predetermined wavelength in an in-plane direction, light having been generated in the active layer by optical coupling with the active layer is introduced, light of the predetermined wavelength having been introduced is diffracted for laser oscillation, and a traveling direction of at least part of light is converted into a vertical direction with respect to the in-plane direction;
wherein, in the diffraction grating, a region except a region opposite to the grating coupler is covered and a region, opposite to the grating coupler, to eject light having been converted into the vertical direction is a surface emitting region; and
wherein a member to cover the diffraction grating is the first electrode and a resonator region to carry out laser oscillation, together with the second electrode opposite to the first electrode is formed.

30. The surface emitting semiconductor laser, described in claim 29, wherein the surface emitting region is provided in end portion of the diffraction grating; and an optical intensity distribution of light ejected from the surface emitting region is maximized in the vicinity of a border between the resonator region and the surface emitting region in a first direction toward the surface emitting region from the resonator region and decreased with separation toward the surface emitting region from the border.

31. The surface emitting semiconductor laser, described in claim 30, wherein a region provided with the diffraction grating when viewed from the side where light is ejected from the surface emitting region has a reed shape whose long side is the first direction.

32. The surface emitting semiconductor laser, described in claim 30, wherein in the diffraction grating, concave portions arranged in the first clad layer with the period are filled with a material having refractive index differing from that of a material for the first clad layer.

33. The surface emitting semiconductor laser, described in claim 32, wherein the concave portions are cavity-shaped concave portions and the cavity-shaped concave portions of the resonator region and the surface emitting region are arranged in a square grid manner in the first direction and in a direction vertical to the first direction.

34. The surface emitting semiconductor laser, described in claim 32, wherein the concave portions of the resonator region are cavity-shaped ones arranged in a square grid manner in the first direction and a direction vertical to the first direction; and the concave portions of the surface emitting region are striped groove-shaped ones arranged in the direction vertical to the first direction and a period of the first direction is arranged so as to be the same as the period of the square grid.

35. The surface emitting semiconductor laser, described in claim 32, wherein the concave portions are cavity-shaped ones and the cavity-shaped concave portions of the resonator region are arranged in a square grid manner in the first direction and a direction vertical to the first direction; and in the cavity-shaped concave portions of the surface emitting region, the period of the direction vertical to the first direction is the same as that of the square grid of the resonator region and a period of the first direction is arranged so as to be differing from the period of the square grid.

36. The surface emitting semiconductor laser, described in claim 32, wherein the concave portions of the resonator region are cavity-shaped ones arranged in a square grid manner in the first direction and in a direction vertical to the first direction; and the concave portions of the surface emitting region are striped groove-shaped ones arranged in the direction vertical to the first direction and a period of the first direction is arranged so as to be differing from the period of the square grid.

37. The surface emitting semiconductor laser, described in claim 35, wherein in the first direction and in a cross-section of the concave portions in a vertical direction of a main flat surface on an opposite side to a surface facing to the active layer of the first clad layer, with regard to the concave portions of the surface emitting region, a width of the concave portions of the first direction is decreased or increased as a depth from the main flat surface is increased and the concave portions are asymmetrical with respect to the axis vertical to the main flat surface.

38. The surface emitting semiconductor laser, described in claim 33, wherein a cross-section of a depth direction of the concave portions from a main flat surface on an opposite side to a surface facing the active layer of the first clad layer are the same, and a cross-section of the concave portions in the resonator region differs from the cross-section of the concave portions in the surface emitting region.

39. The surface emitting semiconductor laser, described in claim 32, wherein a depth of the concave portions from a main flat surface of an opposite side to a surface facing the active layer of the first clad layer differs in the resonator region and the surface emitting region.

40. The surface emitting semiconductor laser, described in claim 39, wherein the depth of the concave portions in the surface emitting region is smaller in the end portion of the surface emitting region in the direction distant from the border than in a vicinity of the border.

41. The surface emitting semiconductor laser, described in claim 30, wherein a width of a region where the diffraction grating in a direction vertical to the first direction is located is a width of the grating coupler irradiated with light or more.

42. In an optical recording head to carry out information recording on a recording medium using light, the optical recording head comprising:
a surface emitting semiconductor laser described in claim 29;
a slider moving relatively to the recording medium; and
a waveguide, in which light irradiated by the surface emitting semiconductor laser is introduced into a side of the slider substantially vertical to the recording surface of the recording medium and the thus-introduced light is propagated toward the recording medium.

43. The optical recording head described in claim 42, wherein the surface emitting semiconductor laser is fixed to the waveguide.

44. An optical recording apparatus comprising the optical recording head described in claim 42 and a recording medium.
